(19) United States
(12) Patent Application Publication
(10) Pub. No.: US 2026/0052847 A1
(43) Pub. Date: Feb. 19, 2026

(54) DISPLAY DEVICE AND ELECTRONIC DEVICE

(71) Applicant: SAMSUNG DISPLAY CO., LTD., Yongin-Si (KR)

(72) Inventors: Xin Xing LI, Yongin-si (KR); Ji Yun KOO, Yongin-si (KR)

(21) Appl. No.: 19/170,116

(22) Filed: Apr. 4, 2025

(30) Foreign Application Priority Data
Aug. 13, 2024 (KR) 10-2024-0108262

(51) Int. Cl. H10K 59/122; H10K 59/124; H10K 59/80

(52) U.S. Cl. CPC H10K 59/122; H10K 59/124; H10K 59/873; H10K 59/8792

(57) ABSTRACT

A display device includes: a substrate; a first and second transistors disposed on the substrate; a passivation layer disposed on the first and second transistors; a connection electrode connected to the first transistor; a sacrificial layer covering an edge of the connection electrode; a first pixel defining layer disposed on the sacrificial layer and including a first opening; a first pixel electrode disposed on the connection electrode; a second pixel electrode disposed on the first pixel defining layer and connected to the second transistor; a second pixel defining layer disposed on the second pixel electrode and including a second opening; a light emitting layer; a common layer disposed on the light emitting layer; a common electrode disposed on the common layer; an encapsulation layer disposed on the common electrode; and a light blocking layer disposed on the encapsulation layer and including a hole that overlaps the first and second openings.

### CROSS-REFERENCE TO RELATED APPLICATION

This application claims priority under 35 U.S.C. § 119 to Korean Patent Application No. 10-2024-0108262 filed on Aug. 13, 2024 in the Korean Intellectual Property Office, the disclosure of which is incorporated by reference herein in its entirety.

### TECHNICAL FIELD

The present invention relates to a display device and electronic device.

### DISCUSSION OF THE RELATED ART

As the information society continues to further develop, the demand for display devices for displaying images and information has increased and diversified. For example, display devices have been applied to various electronic devices such as smartphones, digital cameras, laptop computers, navigation devices, and smart televisions.

The display devices may be flat panel display devices such as liquid crystal display devices, field emission display devices, or light emitting display devices. Generally, the light emitting display device includes an organic light emitting display device including organic light emitting elements, an inorganic light emitting display device including inorganic light emitting elements such as inorganic semiconductors, and a micro light emitting display device including micro light emitting elements.

Since the organic light-emitting display device, which includes the organic light emitting elements, does not require a separate light source such as a backlight unit due to its self-emissive characteristic, the organic emitting display device may have low power consumption, may be configured to be lightweight and thin, and may have high quality characteristics such as a wide viewing angle, high luminance and contrast, and a fast response speed. Accordingly, the organic light emitting has attracted attention as the next-generation display device.

### SUMMARY

According to an embodiment of the present invention, a display device includes: a substrate; a first thin film transistor and a second thin film transistor disposed on the substrate; a passivation layer disposed on the first thin film transistor and the second thin film transistor; a connection electrode disposed on the passivation layer and connected to the first thin film transistor; a sacrificial layer covering an edge of the connection electrode; a first pixel defining layer disposed on the passivation layer and the sacrificial layer and including a first opening; a first pixel electrode disposed on the connection electrode; a second pixel electrode disposed on the first pixel defining layer and connected to the second thin film transistor; a second pixel defining layer disposed on the first pixel defining layer and the second pixel electrode and including a second opening that overlaps the first opening; a light emitting layer including a first organic layer and a second organic layer, wherein the first organic layer is disposed on the first pixel electrode, and the second organic layer is disposed on the second pixel electrode; a common layer disposed on the light emitting layer and the second pixel defining layer; a common electrode disposed on the common layer; an encapsulation layer disposed on the common electrode; and a light blocking layer disposed on the encapsulation layer and including a hole that overlaps the first opening and the second opening.

In an embodiment of the present invention, a side surface and lower surface of the first pixel defining layer form a tip that protrudes beyond a side surface of the sacrificial layer.

In an embodiment of the present invention, the first pixel electrode and the second pixel electrode are separated from each other by the tip of the first pixel defining layer.

In an embodiment of the present invention, the first organic layer and the second organic layer are separated from each other by the tip of the first pixel defining layer.

In an embodiment of the present invention, the display device further includes: a first light emitting element including the first pixel electrode, the first organic layer, the common layer, and the common electrode; and a second light emitting element including the second pixel electrode, the second organic layer, the common layer, and the common electrode.

In an embodiment of the present invention, the first light emitting element overlaps the first opening, and includes a main emission area that extends to an inner peripheral surface of the second pixel electrode, and the second light emitting element includes a surrounding emission area where the second pixel electrode, the second organic layer, the common layer, and the common electrode overlap each other in a thickness direction.

In an embodiment of the present invention, the main emission area overlaps the first opening, the second opening, and the hole, and the surrounding emission area does not overlap the first opening and the hole and overlaps the second opening.

In an embodiment of the present invention, in a first light emitting mode, a same driving voltage is applied to the first pixel electrode and the second pixel electrode through the first thin film transistor and the second thin film transistor, such that light is emitted from the light emitting layer.

In an embodiment of the present invention, in a second light emitting mode, a driving voltage is applied to the first pixel electrode through the first thin film transistor, such that light is emitted from the first organic layer of the light emitting layer, and the second thin film transistor is in an off state and the driving voltage is not applied to the second pixel electrode, such that light is not emitted from the second organic layer of the light emitting layer.

In an embodiment of the present invention, the light blocking layer overlaps the first pixel electrode and the second pixel electrode.

In an embodiment of the present invention, the light blocking layer includes a first light blocking layer and a second light blocking layer, wherein the first light blocking layer includes the hole, and the second light blocking layer is spaced apart from the first light blocking layer and surrounds the first light blocking layer.

In an embodiment of the present invention, the display device further includes a surrounding hole disposed between the first light blocking layer and the second light blocking layer, wherein the surrounding hole does not overlap the first opening and overlaps the second opening.

In an embodiment of the present invention, a corner of the first light blocking layer, where a lower surface and a side surface of the first light blocking layer meet, meets a line that extends from an upper surface of the first pixel electrode, passes through a bent portion of the second organic layer, and meets an end of the second pixel electrode, wherein the bent portion of the second organic layer corresponds to a portion of the first pixel defining layer where an upper surface and a side surface of the first pixel defining layer meet.

According to an embodiment of the present invention, a display device includes a plurality of pixels each including a plurality of sub-pixels, wherein each of the plurality of sub-pixels includes: a substrate; a first thin film transistor and a second thin film transistor disposed on the substrate; a passivation layer disposed on the first thin film transistor and the second thin film transistor; a first pixel electrode disposed on the passivation layer and connected to the first thin film transistor; a second pixel electrode disposed on the passivation layer and connected to the second thin film transistor; a pixel defining layer covering an edge of each of the first pixel electrode and the second pixel electrode and including a first opening and a second opening, wherein the first opening overlaps the first pixel electrode, and the second opening overlaps the second pixel electrode; a light emitting layer including a first organic layer and a second organic layer, wherein the first organic layer is disposed on the first pixel electrode, and the second organic layer is disposed on the second pixel electrode; a common electrode disposed on the light emitting layer and the pixel defining layer; an encapsulation layer disposed on the common electrode; a first light blocking layer disposed on the encapsulation layer and including a hole overlapping the first opening; and a second light blocking layer disposed on the encapsulation layer, and surrounding the first light blocking layer, wherein the second light blocking layer includes a main hole overlapping the first light blocking layer.

In an embodiment of the present invention, the display device further includes: a first light emitting element including the first pixel electrode, the first organic layer, and the common electrode; and a second light emitting element including the second pixel electrode, the second organic layer, and the common electrode.

In an embodiment of the present invention, the first light emitting element includes a main emission area overlapping the first opening and the hole, and the second light emitting element includes a surrounding emission area that overlaps the main hole but does not overlap the main emission area.

In an embodiment of the present invention, in a first light emitting mode, a same driving voltage is applied to the first pixel electrode and the second pixel electrode through the first thin film transistor and the second thin film transistor, such that the first light emitting element and the second light emitting element emit light, and the light is emitted through the hole of the first light blocking layer and the main hole of the second light blocking layer while in the first light emitting mode.

In an embodiment of the present invention, in a second light emitting mode, a driving voltage is applied to the first pixel electrode through the first thin film transistor, such that the first light emitting element emits light, and the second thin film transistor is in an off state and the driving voltage is not applied to the second pixel electrode, such that the second light emitting element does not emit light, and the light emitted from the first light emitting element is emitted through the hole of the first light blocking layer while in the second light emitting mode.

In an embodiment of the present invention, the display device further including a surrounding hole disposed between the first light blocking layer and the second light blocking layer, wherein the surrounding hole does not overlap the main emission area and overlaps the surrounding emission area.

According to an embodiment of the present invention, an electronic device includes: a processor; a memory having stored application programs for execution by the processor; a display device, including: a substrate; a first thin film transistor and a second thin film transistor disposed on the substrate; a passivation layer disposed on the first thin film transistor and the second thin film transistor; a connection electrode disposed on the passivation layer and connected to the first thin film transistor; a sacrificial layer covering an edge of the connection electrode; a first pixel defining layer disposed on the passivation layer and the sacrificial layer and including a first opening; a first pixel electrode disposed on the connection electrode; a second pixel electrode disposed on the first pixel defining layer and connected to the second thin film transistor; a second pixel defining layer disposed on the first pixel defining layer and the second pixel electrode and including a second opening that overlaps the first opening; a light emitting layer including a first organic layer and a second organic layer, wherein the first organic layer is disposed on the first pixel electrode, and the second organic layer is disposed on the second pixel electrode; a common layer disposed on the light emitting layer and the second pixel defining layer; a common electrode disposed on the common layer; an encapsulation layer disposed on the common electrode; and a light blocking layer disposed on the encapsulation layer and including a hole that overlaps the first opening and the second opening; and a user interface configured to sense user input via touch or cursor select of an icon presented on the display device, wherein the processor is caused to execute one or more of the stored application programs upon receipt of the user input.

### BRIEF DESCRIPTION OF THE DRAWINGS

The above and other aspects and features of the present invention will become more apparent by describing in detail embodiments thereof with reference to the attached drawings, in which:

FIG. 1 is a schematic perspective view of an electronic device according to an embodiment of the present invention;

FIG. 2 is a perspective view illustrating a display device that is included in the electronic device according to an embodiment of the present invention;

FIG. 3 is a cross-sectional view of the display device of FIG. 2 viewed from the side;

FIG. 4 is a schematic circuit diagram illustrating a sub-pixel of one pixel of the display device according to an embodiment of the present invention;

FIG. 5 is a plan view illustrating one pixel of the display device according to an embodiment of the present invention;

FIG. 6 is a cross-sectional view taken along line X1-X1′ of FIG. 5;

FIG. 7 is a schematic view illustrating light emission while the display device is operating in a first light emitting mode according to an embodiment of the present invention;

FIG. 8 is a schematic view illustrating light emission while the display device is operating in a second light emitting mode of the display device according to an embodiment of the present invention;

FIGS. 9, 10, 11, 12, 13, 14 and 15 are cross-sectional views illustrating processes of a method of manufacturing the display device according to an embodiment of the present invention;

FIG. 16 is a plan view illustrating one pixel of a display device according to an embodiment of the present invention;

FIG. 17 is a cross-sectional view taken along line X2-X2′ of FIG. 16;

FIG. 18 is a schematic view illustrating light emission while the display device is operating in a first light emitting mode of the display device according to another embodiment;

FIG. 19 is a schematic view illustrating light emission while the display device is operating in a second light emitting mode according to an embodiment of the present invention;

FIG. 20 is a cross-sectional view illustrating a display device according to an embodiment of the present invention;

FIG. 21 is a schematic view illustrating light emission while the display device is operating in a first light emitting mode according to an embodiment of the present invention;

FIG. 22 is a schematic view illustrating light emission while the display device is operating in a second light emitting mode according to an embodiment of the present invention; and

FIG. 23 is a block diagram illustrating an electronic device according to an embodiment of the present invention.

### DETAILED DESCRIPTION OF THE EMBODIMENTS

Features of the present invention will now be described more fully hereinafter with reference to the accompanying drawings, in which embodiments of the present invention are shown. This invention may, however, be embodied in different forms and should not be construed as limited to the embodiments set forth herein.

It will also be understood that when a layer is referred to as being “on” another layer or substrate, it can be directly on the other layer or substrate, or intervening layers may also be present. The same reference numbers indicate the same components throughout the specification and drawings, and thus, redundant descriptions may be omitted or briefly discussed.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present invention may be combined or combined with each other, in part or in whole, and technically various interlocking and driving are possible. Each embodiment may be implemented independently of each other or may be implemented together in an association.

Hereinafter, embodiments of the present invention will be described with reference to the accompanying drawings.

Embodiments of the present invention relate to a display device and an electronic device that incorporates a privacy protection mode, designed to increase user privacy while providing high-quality display functionality. The display device includes a substrate on which are mounted first and second thin-film transistors (TFTs), a passivation layer, pixel electrodes, a light-emitting layer, and a light-blocking layer. This configuration allows for selective light emission and visibility control based on the activation of specific light-emitting elements. The privacy protection mode restricts light visibility to direct viewing angles, preventing onlookers from observing the display from side angles.

In addition, the display device, according to embodiments of the present invention, includes a layered structure that enables separation and control of light-emitting components. Further, a pixel-defining layer includes a tip structure that separates adjacent pixel electrodes and the organic light-emitting layers, ensuring that light emissions from each pixel can be independently managed. The light-emitting layer itself comprises at least two sub-layers: one for the main emission area and another for surrounding emissions, controlled by corresponding pixel electrodes. This separation increases functionality while simplifying the manufacturing process by reducing the need for additional masking steps.

The display device operates in two light-emission modes. In the first mode, all light-emitting elements are activated, providing a standard display experience with no visibility restrictions. In the second mode, privacy mode, only specific light-emitting elements are activated, ensuring light is visible only from direct angles and blocked from side viewing angles. This is achieved by using a combination of light-blocking layers and strategic pixel electrode placement. The privacy mode is particularly useful for applications requiring confidentiality, such as viewing sensitive information in public spaces.

Additionally, the display device's design streamlines the manufacturing process while maintaining durability and display quality. The layered arrangement, including encapsulation layers and light-blocking components, ensures protection against environmental factors like moisture and oxygen. The modular nature of the design, featuring well-defined pixel structures and integrated emission areas, enables scalability and compatibility with various electronic devices, including smartphones, laptops, and wearable displays.

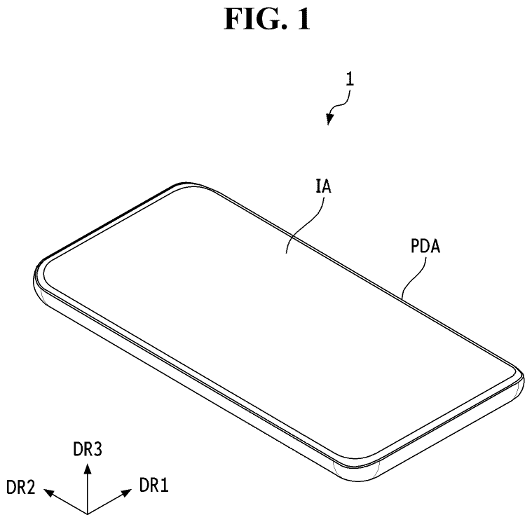

FIG. 1 is a schematic perspective view of an electronic device according to an embodiment of the present invention.

Referring to FIG. 1, an electronic device 1 displays a moving image and/or a still image. The electronic device 1 may refer to all electronic devices that provide display screens. For example, each of televisions, laptop computers, monitors, billboards, the Internet of Things (IoT), mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras, camcorders, and the like, that provide display screens, may be the electronic device 1.

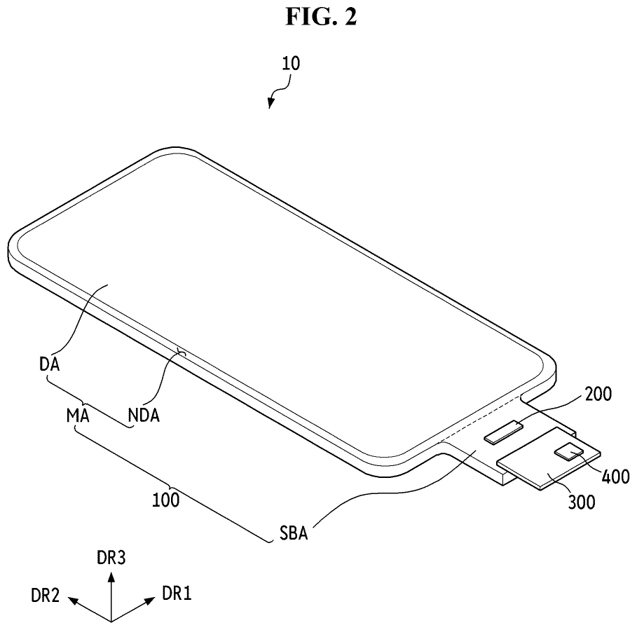

The electronic device 1 may include a display device 10 (see FIG. 2) providing a display screen. Examples of the display device 10 may include an inorganic light emitting diode display device, an organic light emitting display device, a quantum dot light emitting display device, a plasma display device, a field emission display device, and the like. Hereinafter, a case where an organic light emitting diode display device is applied as an example of the display device will be described by way of example, but the present invention is not limited thereto, and the same technical spirit may be applied to other display devices if applicable.

A shape of the electronic device 1 may be variously modified. For example, the electronic device 1 may have a shape such as a rectangular shape with a width greater than a length, a rectangular shape with a length greater than a width, a square shape, a quadrangular shape with rounded corners (vertices), other polygonal shapes, or a circular shape. A shape of a display area DA of the electronic device 1 may also be similar to an overall shape of the electronic device 1. In FIG. 1, the electronic device 1 having a rectangular shape with a length in a second direction DR2 that is larger than its width in the first direction DR1 has been illustrated.

The electronic device 1 may include an image area IA and a peripheral area PA. The peripheral area NDA may be provided outside of the image area IA. For example, the peripheral area PA may at least partially surround the image area IA. The image area IA is an area where a screen may be provided and images may be displayed, and the peripheral area PA is an area where the screen is not provided and images are not displayed. The image area IA may also be referred to as an active area, and the peripheral area PA may also be referred to as a non-active area. For example, the image area IA may occupy substantially the center of the electronic device 1.

FIG. 2 is a perspective view illustrating a display device included in the electronic device according to an embodiment of the present invention.

Referring to FIG. 2, the electronic device 1 according to an embodiment of the present invention may include a display device 10. The display device 10 may provide a screen displayed on the electronic device 1. The display device 10 may have a shape similar to that of the electronic device 1 in plan view. For example, the display device 10 may have a shape similar to a rectangular shape having short sides in a first direction DR1 and long sides in a second direction DR2. A corner where the short side extending in the first direction DR1 and the long side extending in the second direction DR2 meet may be rounded with a curvature, but the present invention is not limited thereto, and may also be right-angled. The shape of the display device 10 in plan view is not limited to the rectangular shape, and may have a shape similar to other polygonal shapes, a circular shape, or an elliptical shape.

The display device 10 may include a display panel 100, a display driver 200, and a circuit board 300.

The display panel 100 may include a main area MA and a sub-area SBA.

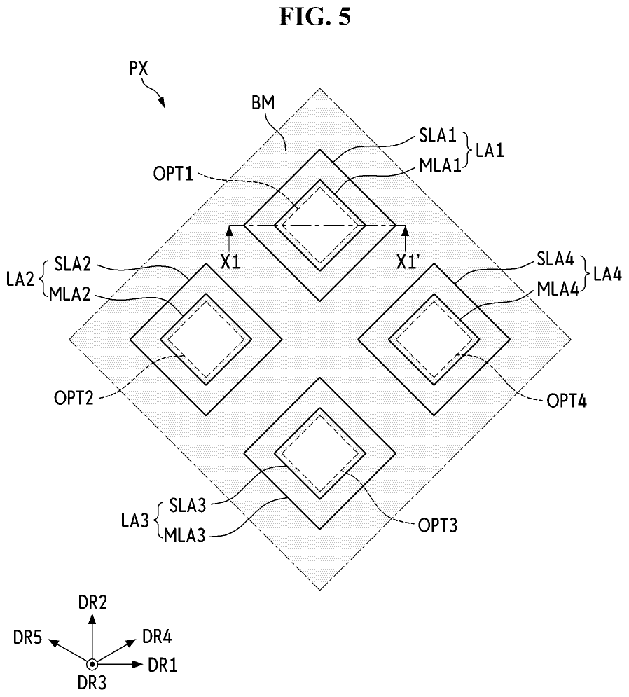

The main area MA may include a display area DA and a non-display area NDA. The display area DA may correspond to the image area IA, and the non-display area NDA may correspond to the peripheral area PA. In the display area DA, pixels PX (see FIG. 5) for displaying an image may be disposed therein. The non-display area NDA disposed around the display area DA. For example, the display area DA may be disposed at the center of the main area MA, and the non-display area NDA may at least partially surround the display area DA. The display area DA may emit light from a plurality of emission areas or a plurality of opening areas. For example, the display panel 100 may include pixel circuits including switching elements, a pixel defining layer defining the emission areas or the opening areas, and self-light emitting elements.

For example, the self-light emitting element may include at least one of an organic light emitting diode (LED) including an organic light emitting layer, a quantum dot LED including a quantum dot light emitting layer, an inorganic LED including an inorganic semiconductor, and a micro LED, but the present invention is not limited thereto.

The non-display area NDA may be an area outside the display area DA. The non-display area NDA may correspond to an edge area or peripheral area of the main area MA of the display panel 100. The non-display area NDA may include a gate driver supplying gate signals to gate lines and fan-out lines (not illustrated) connecting the display driver 200 and the display area DA to each other.

The sub-area SBA may be an area extending from one side of the main area MA. The sub-area SBA may include a flexible material that may be bent, folded, and rolled. For example, when the sub-area SBA is bent, the sub-area SBA may overlap the main area MA in a thickness direction (e.g., a third direction DR3). The sub-area SBA may include the display driver 200 and pad portions connected to the circuit board 300. In an embodiment of the present invention, the sub-area SBA may be omitted, and the display driver 200 and the pad portions may be disposed in the non-display area NDA.

The display driver 200 may output signals and voltages for driving the display panel 100. The display driver 200 may supply data voltages to data lines that are connected to the pixels PX. The display driver 200 may supply source voltages to power lines and supply gate control signals to the gate driver. The display driver 200 may be formed as an integrated circuit (IC) and mounted on the display panel 100 in a chip on glass (COG) manner, a chip on plastic (COP) manner, or an ultrasonic bonding manner. As an example, the display driver 200 may be disposed in the sub-area SBA, and may overlap the main area MA in the thickness direction by bending of the sub-area SBA. As another example, the display driver 200 may be mounted on the circuit board 300.

The circuit board 300 may be attached onto the pad portions of the display panel 100 by using an anisotropic conductive film (ACF). Lead lines of the circuit board 300 may be electrically connected to the pad portions of the display panel 100. The circuit board 300 may be a flexible printed circuit board, a printed circuit board, or a flexible film such as a chip on film.

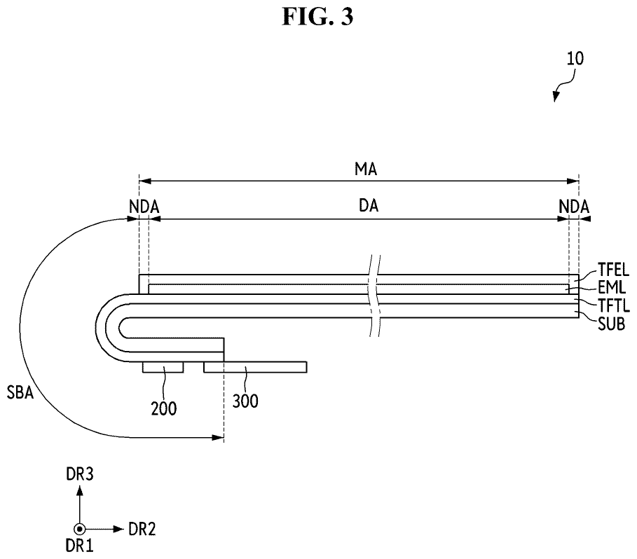

FIG. 3 is a cross-sectional view of the display device of FIG. 2 viewed from the side. FIG. 3 illustrates a state in which the sub-area SBA of the display panel 100 is folded in the display device 10 of FIG. 2.

Referring to FIG. 3, the display panel 100 may include a substrate SUB, a thin film transistor layer TFTL, a light emitting element layer EML, and an encapsulation layer TFEL.

The substrate SUB may be a base substrate or a base member. For example, the substrate SUB may be a rigid substrate or a flexible substrate that may be bent, folded, and rolled. For example, the substrate SUB may include a polymer resin such as polyimide (PI), but the present invention is not limited thereto. In an embodiment of the present invention, the substrate SUB may include a glass material or a metal material.

The thin film transistor layer TFTL may be disposed on the substrate SUB. The thin film transistor layer TFTL may include a plurality of thin film transistors constituting pixel circuits of pixels. The thin film transistor layer TFTL may further include gate lines, data lines, power lines, gate control lines, fan-out lines connecting the display driver 200 and the data lines to each other, and lead lines connecting the display driver 200 and the pad portions to each other. Each of the thin film transistors may include a semiconductor region, a source electrode, a drain electrode, and a gate electrode. For example, when a gate driver is formed on one side of the non-display area NDA of the display panel 100, the gate driver may include thin film transistors.

The thin film transistor layer TFTL may be disposed in the display area DA, the non-display area NDA, and the sub-area SBA. The thin film transistors of each of the pixels, along with the gate lines, the data lines, and the power lines of the thin film transistor layer TFTL, may be disposed in the display area DA. The gate control lines and the fan-out lines of the thin film transistor layer TFTL may be disposed in the non-display area NDA. The lead lines of the thin film transistor layer TFTL may be disposed in the sub-area SBA.

The light emitting element layer EML may be disposed on the thin film transistor layer TFTL. The light emitting element layer EML may include a plurality of light emitting elements each including a first electrode, a second electrode, and a light emitting layer to emit light. The light emitting element layer EML may further include a pixel defining layer defining the pixels. The plurality of light emitting elements of the light emitting element layer EML may be disposed in the display area DA.

In an embodiment of the present invention, the light emitting layer EML may be an organic light emitting layer including an organic material. The light emitting layer EML may include a hole transporting layer, an organic light emitting layer, and an electron transporting layer. When the first electrode receives a voltage through the thin film transistor of the thin film transistor layer TFTL and the second electrode receives a cathode voltage, holes and electrons may move to the organic light emitting layer through the hole transporting layer and the electron transporting layer, respectively, and may be combined with each other in the organic light emitting layer to emit light.

In an embodiment of the present invention, the light emitting element may include a quantum dot light emitting diode including a quantum dot light emitting layer, an inorganic light emitting diode including an inorganic semiconductor, or a micro light emitting diode.

The encapsulation layer TFEL may cover an upper surface and side surfaces of the light emitting element layer EML, and may protect the light emitting element layer EML. The encapsulation layer TFEL may include at least one inorganic film and at least one organic film stacked on each other for encapsulating the light emitting element layer EML.

In an embodiment of the present invention, a touch sensing layer may be disposed on the encapsulation layer TFEL. The touch sensing layer may include a plurality of touch electrodes for sensing a user's touch in a capacitance manner and touch lines connected to the plurality of touch electrodes. For example, the touch sensing layer may sense the user's touch in a mutual capacitance manner or a self-capacitance manner.

In an embodiment of the present invention, a color filter layer may be disposed on the touch sensing layer or the encapsulation layer TFEL. The color filter layer may include a plurality of color filters respectively corresponding to the plurality of emission areas. Each of the color filters may selectively transmit light of a specific wavelength therethrough and block or absorb light of other wavelengths. The color filter layer may absorb a portion of the light entering from the outside of the display device 10, thereby reducing reflected light that is caused by the external light. Accordingly, the color filter layer may prevent distortion of colors due to external light reflection.

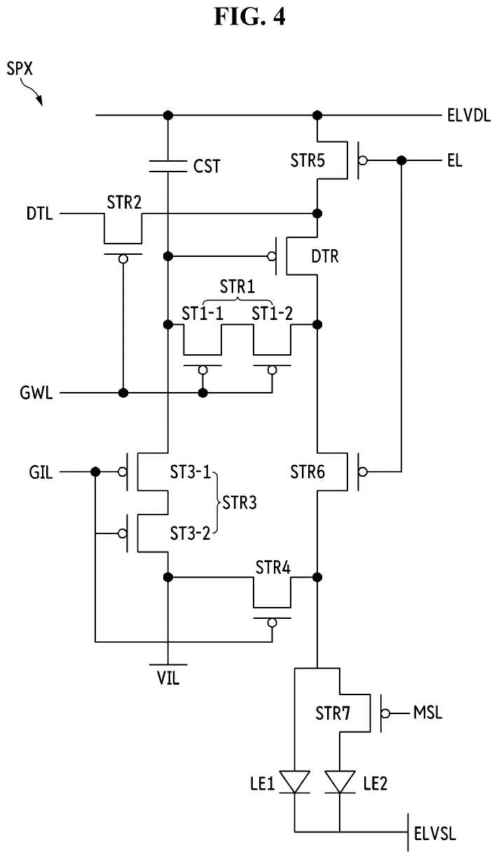

FIG. 4 is a schematic circuit diagram illustrating a sub-pixel of one pixel of the display device according to an embodiment of the present invention.

Referring to FIG. 4, a sub-pixel SPX may include light emitting elements LE1 and LE2, a driving transistor DTR, and first to seventh transistors STR1 to STR7. The light emitting elements LE1 and LE2 may include a first light emitting element LE1 and a second light emitting element LE2.

A first electrode of the driving transistor DTR may be electrically connected to the light emitting elements LE1 and LE2 via the sixth transistor STR6. The driving transistor DTR receives a data signal according to a switching operation of the second transistor STR2 and supplies a driving current to the light emitting elements LE1 and LE2.

A gate electrode of the first transistor STR1 may be connected to a scan write line GWL. A first electrode of the first transistor STR1 may be connected to the first electrode of the driving transistor DTR, and may be connected to pixel electrodes of the light emitting elements LE1 and LE2 via the sixth transistor STR6. A second electrode of the first transistor STR1 may be connected to a first electrode of a capacitor CST, a first electrode of the third transistor STR3, and a gate electrode of the driving transistor DTR. The first transistor STR1 may include a first-first transistor ST1-1 and a first-second transistor ST1-2. However, the first transistor STR1 is not limited thereto, and may also be formed as one transistor. The first transistor STR1 is turned on according to a scan signal that is received through the scan write line GWL, connecting the gate electrode of the driving transistor DTR to the first electrode of the driving transistor DTR, thereby enabling the driving transistor DTR.

A gate electrode of the second transistor STR2 is connected to the scan write line GWL, and a first electrode of the second transistor STR2 is connected to a data line DTL. A second electrode of the second transistor STR2 may be connected to a second electrode of the driving transistor DTR, and may be connected to a first power line ELVDL via the fifth transistor STR5. The second transistor STR2 is turned on according to a scan signal that is received through the scan write line GWL to perform a switching operation of transferring a data signal that is transmitted to the second electrode of the driving transistor DTR through the data line DTL.

A gate electrode of the third transistor STR3 may be connected to a scan initialization line GIL. A second electrode of the third transistor STR3 may be connected to an initialization voltage line VIL. The first electrode of the third transistor STR3 may be connected to the first electrode of the capacitor CST, the second electrode of the first transistor STR1, and the gate electrode of the driving transistor DTR. The third transistor STR3 may include a third-first transistor ST3-1 and a third-second transistor ST3-2. However, the third transistor STR3 is not limited thereto, and may also be formed as one transistor. The third transistor STR3 may be turned on according to a scan initialization signal that is received through the scan initialization line GIL to perform an initialization operation of transferring an initialization voltage to the gate electrode of the driving transistor DTR to initialize a voltage of the gate electrode of the driving transistor DTR.

A gate electrode of the fourth transistor STR4 may be connected to the scan initialization line GIL. A first electrode of the fourth transistor STR4 may be connected to the pixel electrodes of the light emitting elements LE1 and LE2. A second electrode of the fourth transistor STR4 may be connected to the initialization voltage line VIL. The fourth transistor STR4 may be turned on according to a scan initialization signal that is received through the scan initialization line GIL to initialize the pixel electrodes of the light emitting elements LE1 and LE2.

A gate electrode of the fifth transistor STR5 may be connected to an emission control line EL. A first electrode of the fifth transistor STR5 may be connected to the first power line ELVDL. A second electrode of the fifth transistor STR5 is connected to the second electrode of the driving transistor DTR and the second electrode of the second transistor STR2.

A gate electrode of the sixth transistor STR6 may be connected to the emission control line EL. A first electrode of the sixth transistor STR6 may be connected to the first electrode of the driving transistor DTR and the first electrode of the first transistor STR1. A second electrode of the sixth transistor STR6 may be electrically connected to the pixel electrodes of the light emitting elements LE1 and LE2. The fifth transistor STR5 and the sixth transistor STR6 are simultaneously turned on according to an emission control signal that is received through the emission control line EL, allowing a first source voltage from the first power line ELVDL to be supplied to the light emitting elements LE1 and LE2, enabling the driving current to flow through the light emitting elements LE1 and LE2.

A gate electrode of the seventh transistor STR7 may be connected to a light emitting switch line MSL. A first electrode of the seventh transistor STR7 may be connected to the second electrode of the sixth transistor STR6. A second electrode of the seventh transistor STR7 may be electrically connected to the pixel electrode of the second light emitting element LE2. The seventh transistor STR7 is turned on according to a switch signal that is received through the light emitting switch line MSL, allowing the first source voltage from the first power line ELVDL to be supplied to the second light emitting element LE2, enabling the driving current to flow through the second light emitting element LE2.

The first electrode of the capacitor CST may be connected to the gate electrode of the driving transistor DTR, the second electrode of the first transistor STR1, and the first electrode of the third transistor STR3.

A common electrode of the light emitting elements LE1 and LE2 receive a second source voltage through a second power line ELVSL. The light emitting elements LE1 and LE2 receive the driving current from the driving transistor DTR to emit light.

The light emitting elements LE1 and LE2 of the sub-pixel SPX described above may emit light differently depending on light emitting modes that the display device 10 is operating at. For example, when the display device 10 is operating in a first light emitting mode (e.g., a general mode), the first light emitting element LE1 and the second light emitting element LE2 may emit light simultaneously by turning on the seventh transistor STR7. When the display device 10 is operating in a second light emitting mode (e.g., a privacy protection mode), the first light emitting element LE1 may emit light, while the second light-emitting element LE2 is prevented from emitting light by turning off the seventh transistor STR7.

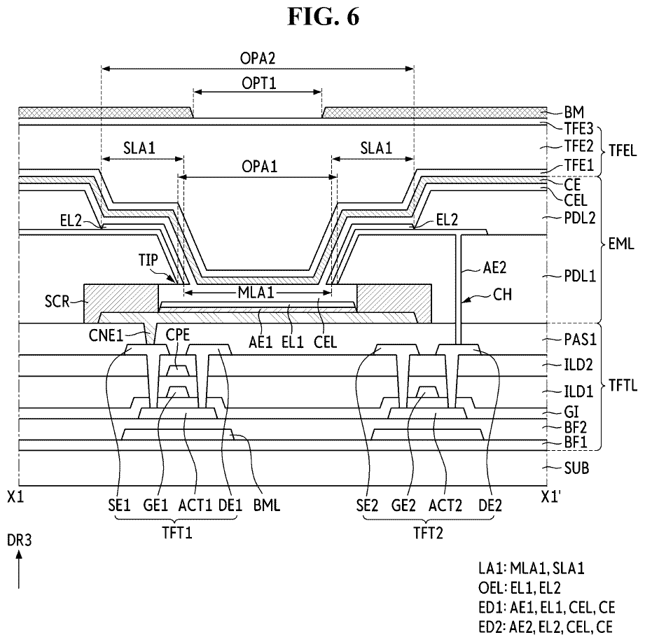

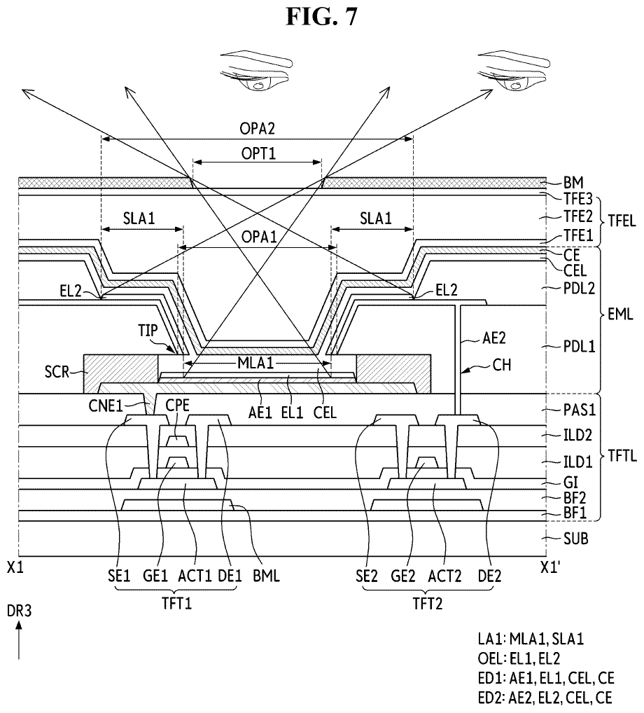

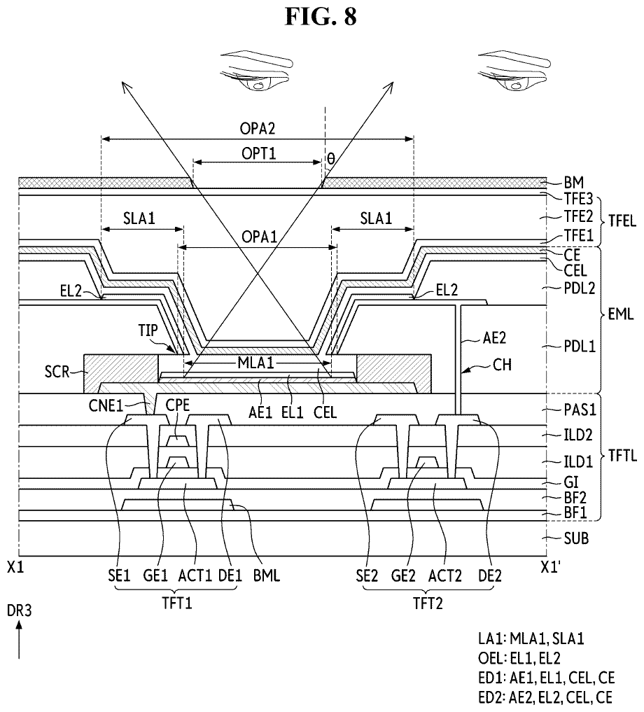

FIG. 5 is a plan view illustrating one pixel of the display device according to an embodiment. FIG. 6 is a cross-sectional view taken along line X1-X1′ of FIG. 5. FIG. 7 is a schematic view illustrating light emission while the display device is operating in a first light emitting mode of the display device according to an embodiment of the present invention. FIG. 8 is a schematic view illustrating light emission while the display device is operating in a second light emitting mode according to an embodiment of the present invention.

Referring to FIG. 5, the display device 10 may include a pixel PX disposed in the display area DA. The pixel PX may include a plurality of emission areas LA1, LA2, LA3, and LA4. For example, the pixel PX may include a first emission area LA1, a second emission area LA2, a third emission area LA3, and a fourth emission area LA4. However, the present invention is not limited thereto. The number of emission areas LA1, LA2, LA3, and LA4 disposed in the pixel PX may be variously modified.

The pixel PX may include one or more light emitting elements. Such light emitting elements may be light emitting elements that emit light of different colors. For example, light emitting elements including the first emission area LA1 may emit light of a first color, which is red light. Light emitting elements including the second emission area LA2 may emit light of a second color, which is blue light, and light emitting elements including the third emission area LA3 may emit light of a third color, which is green light. In addition, light emitting elements including the fourth emission area LA4 may emit the light of the second color, which is the blue light. However, the present invention is not limited thereto.

The respective emission areas LA1, LA2, LA3, and LA4 may emit light of various colors. For example, the first emission area LA1 may emit the light of the first color, which is the red light. The second emission area LA2 may emit the light of the second color, which is the blue light. The third emission area LA3 may emit the light of the third color, which is the green light, and the fourth emission area LA4 may emit the light of the second color, which is the blue light. In an embodiment of the present invention, the respective emission areas LA1, LA2, LA3, and LA4 of the display device 10 may be areas overlapping pixel electrodes, and for example, openings of pixel defining layers PDL1 and PDL2 (see FIG. 6) illustrated in FIG. 6 may correspond to the emission areas LA1, LA2, LA3, and LA4.

Each of the emission areas LA1, LA2, LA3, and LA4 may be defined by a plurality of openings OPA1 and OPA2 formed in pixel defining layers PDL1 and PDL2 (see FIG. 6) of a light emitting element layer EML to be described below. Taking the first emission area LA1 as an example, the first emission area LA1 may be defined (or, e.g., formed) by a first opening OPA1 and a second opening OPA2 of the pixel defining layers that overlap a first pixel electrode AE1 and a second pixel electrode AE2.

The emission areas LA1, LA2, LA3, and LA4 may include main emission areas MLA1, MLA2, MLA3, and MLA4 and surrounding emission areas SLA1, SLA2, SLA3, and SLA4, respectively. For example, the first emission area LA1 may include a first main emission area MLA1 and a first surrounding emission area SLA1. The second emission area LA2 may include a second main emission area MLA2 and a second surrounding emission area SLA2. The third emission area LA3 may include a third main emission area MLA3 and a third surrounding emission area SLA3. The fourth emission area LA4 may include a fourth main emission area MLA4 and a fourth surrounding emission area SLA4.

Each of the main emission areas MLA1, MLA2, MLA3, and MLA4 of the emission areas LA1, LA2, LA3, and LA4 may correspond to a first opening OPA1 of a first pixel defining layer PDL1 (see FIG. 6), and each of the surrounding emission areas SLA1, SLA2, SLA3, and SLA4 of the emission areas LA1, LA2, LA3, and LA4 may correspond to a second opening OPA2 of a second pixel defining layer PDL2 (see FIG. 6). For example, each of the surrounding emission areas SLA1, SLA2, SLA3, and SLA4 may be an area of the second opening OPA2 of the second pixel defining layer PDL2 (see FIG. 6) excluding the first opening OPA1 of the first pixel defining layer PDL1 (see FIG. 6).

The plurality of emission areas LA1, LA2, LA3, and LA4 may be disposed in a PenTile™ type, for example, a diamond PenTile™ type. For example, the first emission area LA1 and the third emission area LA3 may be disposed to be spaced apart from each other in the second direction DR2, and the second emission area LA2 and the fourth emission area LA4 may be spaced apart from each other in the first direction DR1 and may be spaced apart from the first emission area LA1 and third emission area LA3 adjacent thereto, in a fourth direction DR4 or a fifth direction DR5.

In an embodiment of the present invention, areas or sizes of the first to fourth emission areas LA1, LA2, LA3, and LA4 may be the same as or different from each other. In an embodiment of FIG. 5, the areas or the sizes of the first to fourth emission areas LA1, LA2, LA3, and LA4 may be the same as each other. In an embodiment of the present invention, an area of the first emission area LA1 may be greater than each of areas of the second to fourth emission areas LA2, LA3, and LA4, and an area of the third emission area LA3 may be greater than each of areas of the second emission area LA2 and the fourth emission area LA4.

Intensities of the light emitted from the respective emission areas LA1, LA2, LA3, and LA4 may vary based on their sizes. A color perception of a screen displayed on the display device 10 or the electronic device 1 may be controlled by adjusting the sizes of the respective emission area LA1, LA2, LA3, and LA4. The sizes and the areas of the respective emission areas LA1, LA2, LA3, and LA4 may be freely adjusted according to a color perception of the screen required by the display device 10 and the electronic device 1. In addition, the areas of the respective emission areas LA1, LA2, LA3, and LA4 may be related to light efficiency, lifespan of light emitting elements ED, and the like, and may have a trade-off relationship with reflection by external light. The areas of the respective emission areas LA1, LA2, LA3, and LA4 may be adjusted in consideration of the above-described factors.

The display device 10 may include a light blocking layer BM disposed on the respective emission areas LA1, LA2, LA3, and LA4.

The light blocking layer BM may be disposed over the display area DA. For example, the light blocking layer BM may be disposed over the entire display area DA. The light blocking layer BM may include a plurality of holes OPT1, OPT2, OPT3, and OPT4 disposed to respectively correspond to the plurality of emission areas LA1, LA2, LA3, and LA4. In addition, the holes OPT1, OPT2, OPT3, and OPT4 of the light blocking layer BM may be disposed to correspond to the openings OPA1 and OPA2 of the pixel defining layers PDL1 and PDL2 (see FIG. 6), respectively. The light blocking layer BM may cover the display area DA except for an area of the display area DA where the holes OPT1, OPT2, OPT3, and OPT4 are disposed. The holes OPT1, OPT2, OPT3, and OPT4 of the light blocking layer BM may be areas where light emitted from light emitting elements corresponding to the respective emission areas LA1, LA2, LA3, and LA4 is emitted. The plurality of holes OPT1, OPT2, OPT3, and OPT4 may include a first hole OPT1 overlapping the first emission area LA1, a second hole OPT2 overlapping the second emission area LA2, a third hole OPT3 overlapping the third emission area LA3, and a fourth hole OPT4 overlapping the fourth emission area LA4.

An area of each of the plurality of holes OPT1, OPT2, OPT3, and OPT4 in plan view may be smaller than an area of each of the emission areas LA1, LA2, LA3, and LA4 in plan view. For example, the first hole OPT1 may have an area that is smaller than the area of the first emission area LA1 in plan view. The second hole OPT2 may have an area that is smaller than the area of the second emission area LA2 in plan view. The third hole OPT3 may have an area that is smaller than the area of the third emission area LA3 in plan view, and the fourth hole OPT4 may have an area that is smaller than the area of the fourth emission area LA4 in plan view.

Hereinafter, a cross-sectional structure of the display device 10 will be described with reference to FIG. 6.

Referring to FIG. 6, the display panel 10 may include a substrate SUB, a thin film transistor layer TFTL, a light emitting element layer EML, an encapsulation layer TFEL, and a light blocking layer BM.

The substrate SUB may be a base substrate or a base member. The substrate SUB may be a rigid substrate or a flexible substrate that may be bent, folded, and rolled. As an example, the substrate SUB may include a polymer resin such as polyimide (PI), but is not limited thereto. As another example, the substrate SUB may include a glass material or a metal material.

The thin film transistor layer TFTL may include a first buffer layer BF1, bottom metal layers BML, a second buffer layer BF2, a first thin film transistor TFT1, a second thin film transistor TFT2, a gate insulating layer GI, a first interlayer insulating layer ILD1, a capacitor electrode CPE, a second interlayer insulating layer ILD2, a first passivation layer PAS1, and a first connection electrode CNE1.

The first buffer layer BF1 may be disposed on the substrate SUB. The first buffer layer BF1 may include an inorganic film capable of preventing permeation of air or moisture. For example, the first buffer layer BF1 may include a plurality of inorganic films that are alternately stacked on the substrate SUB.

The bottom metal layers BML may be disposed on the first buffer layer BF1. For example, the bottom metal layer BML may be formed as a single layer or multiple layers including any one of molybdenum (Mo), aluminum (Al), chromium (Cr), gold (Au), titanium (Ti), nickel (Ni), neodymium (Nd), and copper (Cu), or alloys thereof. The bottom metal layers BML may be disposed to overlap semiconductor layers ACT1 and ACT2 of the respective thin film transistors TFT1 and TFT2. For example, the bottom metal layers BML may be disposed between the first buffer layer BFL1 and the semiconductor layers ACT1 and ACT2.

The second buffer layer BF2 may cover the first buffer layer BF1 and the bottom metal layer BML. The second buffer layer BF2 may include an inorganic film capable of preventing permeation of air or moisture. For example, the second buffer layer BF2 may include a plurality of inorganic films that are alternately stacked on the first buffer layer BF1 and the bottom metal layer BML.

The respective thin film transistors TFT1 and TFT2 may be disposed on the second buffer layer BF2, and may constitute a pixel circuit of each of a plurality of pixels. For example, the first thin film transistor TFT1 may be the driving transistor DTR (see FIG. 4) of the pixel circuit, and the second thin film transistor TFT2 may be the seventh transistor STR7 (see FIG. 4) of the pixel circuit. The respective thin film transistors TFT1 and TFT2 may include the semiconductor layers ACT1 and ACT2, source electrodes SE1 and SE2, drain electrodes DE1 and DE2, and gate electrodes GE1 and GE2, respectively. For example, the first thin film transistor TFT1 may include a first semiconductor layer ACT1, a first gate electrode GE1, a first source electrode SE1, and a first drain electrode DE1, and the second thin film transistor TFT2 may include a second semiconductor layer ACT2, a second gate electrode GE2, a second source electrode SE2, and a second drain electrode DE2.

The first semiconductor layer ACT1 and the second semiconductor layer ACT2 may be disposed on the second buffer layer BF2. The respective semiconductor layers ACT1 and ACT2 may overlap the respective bottom metal layers BML and the respective gate electrodes GE1 and GE2 in the thickness direction. The respective semiconductor layer ACT1 and ACT2 may be insulated from the respective gate electrodes GE1 and GE2 by the gate insulating layer GI. In the respective semiconductor layers ACT1 and ACT2, a source region and a drain region may be formed by making semiconductor materials conductors. The source and drain regions may be formed through doping processes, where specific impurities are introduced into the semiconductor layers ACT1 and ACT2 to create regions with excess electrons (n-type) or holes (p-type), enabling controlled electrical conductivity necessary for transistor operation.

The gate insulating layer GI may be disposed on the respective semiconductor layers ACT1 and ACT2. For example, the gate insulating layer GI may cover the respective semiconductor layers ACT1 and ACT2 and the second buffer layer BF2, and may insulate the respective semiconductor layers ACT1 and ACT2 and the respective gate electrodes GE1 and GE2 from each other. The gate insulating layer GI may include contact holes through which the respective source electrodes SE1 and SE2 and the respective drain electrodes DE1 and DE2 penetrate.

The first gate electrode GE1 and the second gate electrode GE2 may be disposed on the gate insulating layer GI. The respective gate electrodes GE1 and GE2 may overlap the respective semiconductor layers ACT1 and ACT2 with the gate insulating layer GI interposed therebetween. For example, the first gate electrode GE1 may overlap a channel region of the first semiconductor layer ACT1, and the second gate electrode GE2 may overlap a channel region of the second semiconductor layer ACT2.

The first interlayer insulating layer ILD1 may cover the respective gate electrodes GE1 and GE2 and the gate insulating layer GI. The first interlayer insulating layer ILD1 may include contact holes through which the respective source electrodes SE1 and SE2 and the respective drain electrodes DE1 and DE2 penetrate. The contact holes of the first interlayer insulating layer ILD1 may be connected to the contact holes of the gate insulating layer GI and contact holes of the second interlayer insulating layer ILD2, which is disposed on the first interlayer insulating layer ILD1.

The capacitor electrode CPE may be disposed on the first interlayer insulating layer ILD1. The capacitor electrode CPE may overlap the first gate electrode GE1 in the thickness direction. The capacitor electrode CPE and the first gate electrode GE1 may form a capacitor, enabling the storage of charge to support the operation of the first thin film transistor TFT1 (the driving transistor DTR of FIG. 4).

The second interlayer insulating layer ILD2 may cover the capacitor electrode CPE and the first interlayer insulating layer ILD1. The second interlayer insulating layer ILD2 may include contact holes through which the respective source electrodes SE1 and SE2 and the respective drain electrodes DE1 and DE2 penetrate. The contact holes of the second interlayer insulating layer ILD2 may be connected to the contact holes of the first interlayer insulating layer ILD1 and the contact holes of the gate insulating layer GI.

The respective source electrodes SE1 and SE2 and the respective drain electrodes DE1 and DE2 may be disposed on the second interlayer insulating layer ILD2. For example, the first source electrode SE1 and the first drain electrode DE1 may be disposed to overlap the first semiconductor layer ACT1, and may be connected to the first semiconductor layer ACT1 through the contact holes. The second source electrode SE2 and the second drain electrode DE2 may be disposed to overlap the second semiconductor layer ACT2, and may be connected to the second semiconductor layer ACT2 through the contact holes.

The first passivation layer PAS1 may be disposed on the respective source electrodes SE1 and SE2 and the respective drain electrodes DE1 and DE2. For example, the passivation layer PAS1 may cover the thin film transistors TFT1 and TFT2. The first passivation layer PAS1 may protect the respective thin film transistors TFT1 and TFT2. The first passivation layer PAS1 may include a contact hole through which the first connection electrode CNE1 penetrates.

The first connection electrode CNE1 may be disposed on the first passivation layer PAS1. The first connection electrode CNE1 may electrically connect the first source electrode SE1 of the first thin film transistor TFT1 and the first pixel electrode AE1 to each other through the contact hole of the first passivation layer PAS1.

The light emitting element layer EML may be disposed on the thin film transistor layer TFTL. The light emitting element layer EML may include a first light emitting element ED1, a second light emitting element ED2, the first pixel defining layer PDL1, the second pixel defining layer PDL2, and a sacrificial layer SCR. The first light emitting element ED1 may include the first pixel electrode AE1, a light emitting layer OEL, a common layer CEL, and a common electrode CE. The second light emitting element ED2 may include the second pixel electrode AE2, a light emitting layer OEL, a common layer CEL, and a common electrode CE.

The sacrificial layer SCR may be disposed on the first passivation layer PAS1 and the first connection electrode CNE1. The sacrificial layer SCR may surround the first connection electrode CNE1 in plan view, and cover edges of the first connection electrode CNE1. The sacrificial layer SCR may expose a portion of an upper surface of the first connection electrode CNE1. For example, the sacrificial layer SCR may surround the first pixel electrode AE1 and the first organic layer EL1. As another example, the first pixel electrode AE1, the first organic layer EL1, and the common layer CEL may be disposed in an opening of the sacrificial layer SCR, which exposes the portion of the upper surface of the first connection electrode CNE1. The sacrificial layer SCR may include a conductive material to form a tip TIP of the first pixel defining layer PDL1, which is to be described later. For example, the sacrificial layer SCR may include any one of silver (Ag), molybdenum (Mo), aluminum (Al), chromium (Cr), gold (Au), titanium (Ti), nickel (Ni), neodymium (Nd), and copper (Cu), or alloys thereof.

The first pixel defining layer PDL1 may include the first opening OPA1, and may be disposed on the first passivation layer PAS1 and the sacrificial layer SCR. The first opening OPA1 of the first pixel defining layer PDL1 may expose a portion of the first pixel electrode AE1. The first pixel defining layer PDL1 may include polyimide (PI). In embodiments of the present invention, the first pixel defining layer PDL1 may include a colorant in which red, green, and blue are mixed with each other, a black colorant, or carbon black.

A side surface of the first pixel defining layer PDL1 may protrude outwardly from a side surface of the sacrificial layer SCR. For example, the first pixel defining layer PDL1 may include a tip TIP at which the side surface and a lower surface thereof protrude beyond the sacrificial layer SCR. For example, the side surface of the first pixel defining layer PDL1 may be slanted and may form an angle, which is less than 90 degree, with the lower surface of the first pixel defining layer PDL1. For example, the tip TIP may protrude toward an inner region of the organic light-emitting element. As another example, the TIP may protrude toward an inner region of the first opening of the first pixel defining layer PDL1. The tip TIP of the first pixel defining layer PDL1 may have a function of allowing pixel electrodes AE1 and AE2 and a light emitting layer OEL to be described later to be stacked to be spaced apart from each other, respectively. For example, the tip TIP of the first pixel defining layer PDL1 may allow the first pixel electrode AE1 and a first organic layer EL1 of the light emitting layer OEL to be separated from the second pixel electrode AE2 and a second organic layer EL2 while being stacked on each other.

The first pixel electrode AE1 may be disposed on the first connection electrode CNE1. The first pixel electrode AE1 may be disposed to overlap the first opening OPA1 of the first pixel defining layer PDL1. For example, the first opening OPA1 may partially expose the first electrode AE1. The first pixel electrode AE1 may be disposed on the upper surface of the first connection electrode CNE1, and may be disposed to partially overlap the tip TIP of the first pixel defining layer PDL1. For example, the first pixel electrode AE1 may be entirely disposed on the upper surface of the first connection electrode CNE1. The first pixel electrode AE1 may be electrically connected to the first source electrode SE1 of the first thin film transistor TFT1 through the first connection electrode CNE1.

The second pixel electrode AE2 may be disposed on the first pixel defining layer PDL1. The second pixel electrode AE2 may be disposed to be spaced apart from the first pixel electrode AE1. The second pixel electrode AE2 may be disposed on an upper surface and the side surface of the first pixel defining layer PDL1. The second pixel electrode AE2 may be disposed to partially overlap the first pixel electrode AE1 while being disposed on the side surface of the first pixel defining layer PDL1. The second pixel electrode AE2 may be electrically connected to the second drain electrode DE2 of the second thin film transistor TFT2 through a contact hole CH that is formed in the first pixel defining layer PDL1.

The first pixel electrode AE1 and the second pixel electrode AE2 may be disposed to be spaced apart from each other, and may be disposed to be separated from each other by the tip TIP of the first pixel defining layer PDL1. For example, the first pixel electrode AE1 and the second pixel electrode AE2 may be reflective electrodes. The reflective electrode may be formed as a stacked structure of a transparent conductive layer and a reflective layer. For example, the reflective electrode may be formed as a stacked structure (ITO/Al/ITO) of aluminum and indium tin oxide (ITO) or a stacked structure (ITO/APC/ITO) of an APC alloy and ITO.

The second pixel defining layer PDL2 may include the second opening OPA2, and may be disposed on the first pixel defining layer PDL1 and the second pixel electrode AE2. The second opening OPA2 of the second pixel defining layer PDL2 may expose a portion of the second pixel electrode AE2, and may expose the first opening OPA1 of the first pixel defining layer PDL1. For example, the second pixel defining layer PDL2 may include the same material as the first pixel defining layer PDL1. However, the present invention is not limited thereto.

The light emitting layer OEL may be disposed on the first pixel electrode AE1 and the second pixel electrode AE2. The light emitting layer OEL may include a first organic layer EL1 and a second organic layer EL2. The first organic layer EL1 may be disposed on the first pixel electrode AE1, and the second organic layer EL2 may be disposed on the second pixel electrode AE2. An area of the first organic layer EL1 may be greater than an area of the first opening OPA1 of the first pixel defining layer PDL1. A side surface of the first organic layer EL1 may overlap the first pixel defining layer PDL1. For example, only a portion of the first organic layer EL1 may be exposed by the first opening of the first pixel defining layer PDL1. A side surface of the second organic layer EL2 may be adjacent to a side surface of the second pixel defining layer PDL2. For example, a side surface of the second organic layer EL2 may be in contact with a side surface of the second pixel defining layer PDL2.

The first organic layer EL1 and the second organic layer EL2 may be disposed to be spaced apart from each other. For example, the first organic layer EL1 and the second organic layer EL2 may be disposed to be vertically spaced apart from each other. As described above, due to the tip TIP of the first pixel defining layer PDL1, light emitting materials may be stacked to be separated from each other when the light emitting layer OEL is stacked. That is, the light emitting layer OEL may include the first organic layer EL1 and the second organic layer EL2 separated from each other by the tip TIP of the first pixel defining layer PDL1.

The common layer CEL may be disposed on the light emitting layer OEL and the second pixel defining layer PDL2. The common layer CEL may be disposed to fill an area (or, e.g., space) that is formed by the lower surface of the first pixel defining layer PDL2 and the side surface of the sacrificial layer SCR and may be disposed on the first organic layer EL1 in that area. That is, the common layer CEL may be disposed continuously without being separated by the tip TIP of the first pixel defining layer PDL1. The common layer CEL may be disposed on the first pixel defining layer PDL1, the sacrificial layer SCR, the first organic layer EL1, and the second pixel defining layer PDL2. For example, the common layer CEL may be in contact with each of the first pixel defining layer PDL1, the sacrificial layer SCR, the first organic layer EL1, and the second pixel defining layer PDL2. The common layer CEL is not divided for each of the plurality of pixels, and may be disposed continuously over all the pixels. The common layer CEL may be functional layers contributing to a light emitting function of the light emitting layer OEL. For example, the common layer CEL may include one or more of a charge generation layer, an electron transporting layer, or an electron injection layer.

The common electrode CE may be disposed on the common layer CEL. For example, the common electrode CE is not divided for each of the plurality of pixels, and may be implemented in the form of an electrode that is common to all the pixels. The common electrode CE may receive a common voltage or a low potential voltage. When the respective pixel electrodes AE1 and AE2 receive a voltage corresponding to a data voltage, and the common electrode CE receives the low potential voltage, a potential difference is formed between the respective pixel electrodes AE1 and AE2 and the common electrode CE, causing the light emitting layer OEL to emit the light.

The light emitting element layer EML may include the first emission area LA1. The first emission area LA1 may include the first main emission area MLA1 and the first surrounding emission area SLA1. The first main emission area MLA1 may be an area where light is emitted from the first light emitting element ED1, and the first surrounding emission area SLA1 may be an area where light is emitted from the second light emitting element ED2. The first main emission area MLA1 may be an area at least partially surrounded by a side surface of the second pixel electrode AE2 (e.g., an area formed or defined by an inner peripheral surface of the second pixel electrode AE2) in plan view, and the first surrounding emission area SLA1 may be an area from the side surface of the second pixel electrode AE2 to the side surface of the second organic layer EL2 of the light emitting layer OEL in plan view. For example, the main emission area MLA1 may extend to an inner peripheral surface of the second pixel electrode AE2. For example, the first surrounding emission area SLA1 may be an area of the second opening OPA2 of the second pixel defining layer PDL2 excluding the first main emission area MLA1.

The first main emission area MLA1 may overlap the first opening OPA1 of the first pixel defining layer PDL1, the second opening OPA2 of the second pixel defining layer PDL2, and the first hole OPT1 of the light blocking layer BM. The first surrounding emission area SLA1 might not overlap the first opening OPA1 of the first pixel defining layer PDL1 and the first hole OPT1 of the light blocking layer BM, and may overlap the second opening OPA2 of the second pixel defining layer PDL2. However, the present invention is not limited thereto. For example, the first surround emission area SLA1 may overlap a portion of the first opening of the first pixel defining area PDL1. An area of the first main emission area MLA1 may be smaller than the area of the first opening OPA1 of the first pixel defining layer PDL1, and may be smaller than an area of the second opening OPA2 of the second pixel defining layer PDL2.

In addition, the encapsulation layer TFEL may be disposed on the light emitting element layer EML. The encapsulation layer TFEL may be disposed on the common electrode CE, and may cover the light emitting elements ED1 and ED2. The encapsulation layer TFEL may include at least one inorganic film to prevent oxygen or moisture from permeating into the light emitting element layer EML. The encapsulation layer TFE may include at least one organic film to protect the light emitting element layer EML from foreign substances such as dust.

In an embodiment of the present invention, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2, which is disposed between the first encapsulation layer TFE1 and the third encapsulation layer TFE3, may be an organic encapsulation layer.

Each of the first encapsulation layer TFE1 and the third encapsulation layer TFE3 may include one or more inorganic insulating materials. The inorganic insulating material may include, for example, aluminum oxide, titanium oxide, tantalum oxide, hafnium oxide, zinc oxide, silicon oxide, silicon nitride, and/or silicon oxynitride.

The second encapsulation layer TFE2 may include a polymer-based material. The polymer-based material may include, for example, an acrylic resin, an epoxy-based resin, polyimide, polyethylene, and the like. For example, the second encapsulation layer TFE2 may include an acrylic resin such as polymethyl methacrylate or polyacrylic acid. The second encapsulation layer TFE2 may be formed by curing a monomer or applying a polymer.

The light blocking layer BM may be disposed on the encapsulating layer TFEL. The light blocking layer BM may overlap the first pixel electrode AE1 and the second pixel electrode AE2, and may include the first hole OPT1 disposed to overlap the first main emission area MLA1. For example, the first hole OPT1 may be disposed to overlap the first pixel electrode AE1, the first organic layer EL1, the first main emission area MLA1, the first opening OPA1 of the first pixel defining layer PDL1, and the second opening OPA2 of the second pixel defining layer PDL2.

An area or a size of the first hole OPT1 may be smaller than an area or a size of the first pixel electrode AE1 and may be smaller than an area or a size of the first main emission area MLA1. In addition, the area or the size of the first hole OPT1 may be smaller than an area or a size of the first opening OPA1 of the first pixel defining layer PDL1. However, the present invention is not limited thereto, and the area or the size of the first hole OPT1 may also be the same as or greater than the area or the size of the first pixel electrode AE1 and be the same as or greater than the area or the size of the first main emission area MLA1 so that light emitted from the first main emission area MLA1 is not viewed by a user from a side surface of the display device 10. In addition, the area or the size of the first hole OPT1 may also be the same as or greater than the area or the size of the first opening OPA1 of the first pixel defining layer PDL1.

The light blocking layer BM may include a light absorbing material. For example, the light blocking layer BM may include an inorganic black pigment or an organic black pigment. For example, the inorganic black pigment may be carbon black, and the organic black pigment may include at least one of Lactam Black, Perylene Black, and Aniline Black, but the present invention is not limited thereto. The light blocking layer BM may prevent color mixing due to permeation of visible light to improve a color gamut of the display device 10. In an embodiment of the present invention, the light blocking layer BM may have a thickness of about 1 μm to about 3 μm or about 1.5 μm.

In the display device 10 according to an embodiment of the present invention, side visibility may be adjusted according to light emitting modes of the first light emitting element ED1 and the second light emitting element ED2 in one emission area (e.g., the first emission area).

In the first light emitting mode, while the device is in a state (e.g., being used by user) in which the side visibility does not need to be limited, both the first light emitting element ED1 and the second light emitting element ED2 may emit light. As described above with reference to FIG. 4, in the first light emitting mode, a driving voltage is applied to the first pixel electrode AE1 through the first thin film transistor TFT1 (DTR in FIG. 4), such that the first light emitting element ED1 may emit light. In addition, the same driving voltage is applied to the second pixel electrode AE2 through the second thin film transistor TFT2 (STR7 in FIG. 4), such that the second light emitting element ED2 may emit light. As illustrated in FIG. 7, when both the first light emitting element ED1 and the second light emitting element ED2 emit the light in the first light emitting mode, the light emitted from the first emission area LA1 may be viewed by the user regardless of a direction from which the display device 10 is viewed.

In addition, in the second light emitting mode of the display device 10, while the display device 10 is in a state (e.g., being used by user) where the side visibility needs to be limited, only the first light emitting element ED1 may emit the light. In the second light emitting mode, the driving voltage is applied to the first pixel electrode AE1 through the first thin film transistor TFT1 (DTR in FIG. 4), such that the first light emitting element ED1 may emit the light. In addition, the second thin film transistor TFT2 (STR7 in FIG. 4) is turned off and the driving voltage is not applied (e.g., is blocked) to the second pixel electrode AE2, such that the second light emitting element ED2 does not emit the light.

For example, as illustrated in FIG. 8, when only the first light emitting element ED1 emits the light in the second light emitting mode, the light may be emitted through the first hole OPT1 of the light blocking layer BM and may be blocked by the light blocking layer BM at a specific viewing angle. In the second light emitting mode, since the second light emitting element ED2 does not emit the light a screen of the display device 10 may be visible only to a user viewing it from the front of the display area DA of the display device 10 and might not be visible to someone viewing it at a specific viewing angle θ or from a side of the display area DA. Here, the specific viewing angle θ may be about 60° or less. Accordingly, the display device 10 may provide the privacy protection mode to the user.

Hereinafter, a method of manufacturing the display device 10 according to an embodiment of the present invention will be described.

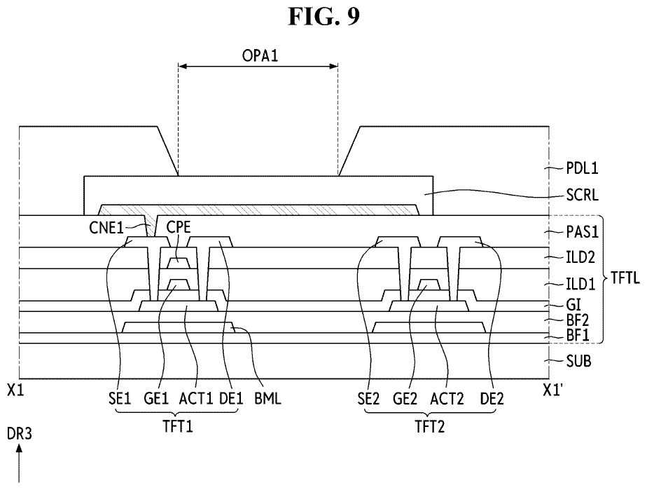

FIGS. 9 to 15 are cross-sectional views illustrating processes of a method of manufacturing the display device according to an embodiment of the present invention. FIGS. 9 to 15 illustrate manufacturing processes of a cross section of one sub-pixel of the display device corresponding to FIG. 6.

First, referring to FIG. 9, the substrate SUB on which the thin film transistor layer TFTL is formed is provided. For example, the first buffer layer BF1, the bottom metal layers BML, the second buffer layer BF2, the first thin film transistor TFT1, the second thin film transistor TFT2, the gate insulating layer GI, the first interlayer insulating layer ILD1, the capacitor electrode CPE, the second interlayer insulating layer ILD2, the first passivation layer PAS1, and the first connection electrode CNE1 are sequentially formed on the substrate SUB. Such components may be formed by using a technique such as a deposition method, a solution process, or a photo process.

A sacrificial material layer SCRL is formed on the first connection electrode CNE1. The sacrificial material layer SCRL may be formed by stacking a conductive material on the first connection electrode CNE1 and the passivation layer PAS1 and then patterning the conductive material by using a photo process. For example, The sacrificial material layer SCRL may be formed to completely cover the first connection electrode CNE1.

Subsequently, the first pixel defining layer PDL1 is formed on the substrate SUB on which the sacrificial material layer SCRL is formed. For example, the first pixel defining layer PDL1 may be formed on the sacrificial material layer SCRL. The first pixel defining layer PDL1 may be formed by using a solution process such as spin coating, inkjet printing, or slit coating. In addition, the first opening OPA1 exposing a portion of an upper surface of the sacrificial material layer SCRL is formed using a photo process.

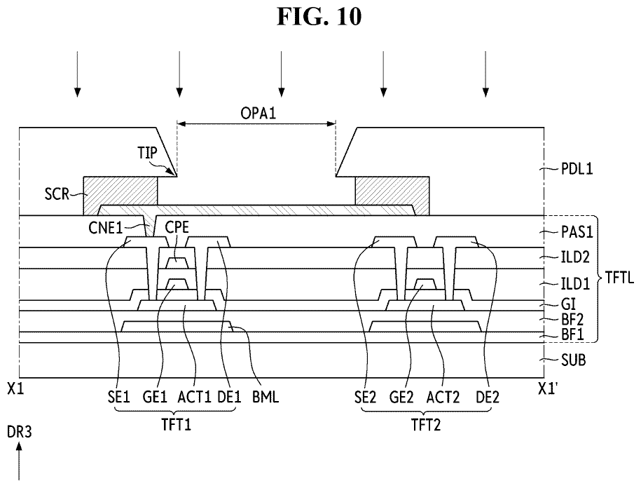

Next, referring to FIG. 10, the sacrificial layer SCR is formed by using a first etching process. The sacrificial layer SCR is formed by etching the sacrificial material layer SCRL using the first pixel defining layer PDL1 as a mask. Here, the first etching process may be a wet etching process. The sacrificial material layer SCRL may be etched by an etchant applied through the first opening OPA1 to expose a portion of the first connection electrode CNE1. In addition, the sacrificial material layer SCRL is over-etched inwardly from the side surface of the first pixel defining layer PDL1, and the tip TIP at which the side surface of the first pixel defining layer PDL1 protrudes from the side surface of the sacrificial layer SCR is formed. For example, a portion of the sacrificial material layer SCRL that overlaps a lower surface of the first pixel defining layer PDL1 may be removed during the etching process.

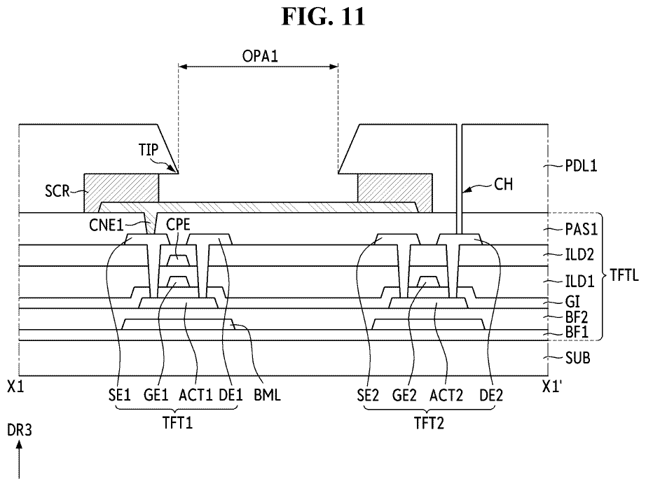

Subsequently, referring to FIG. 11, the contact hole CH is formed using a second etching process. The contact hole CH may penetrate through the first pixel defining layer PDL1 and the first passivation layer PAS1 to expose the second drain electrode DE2 of the second thin film transistor TFT2. The second etching process may be a dry etching process.

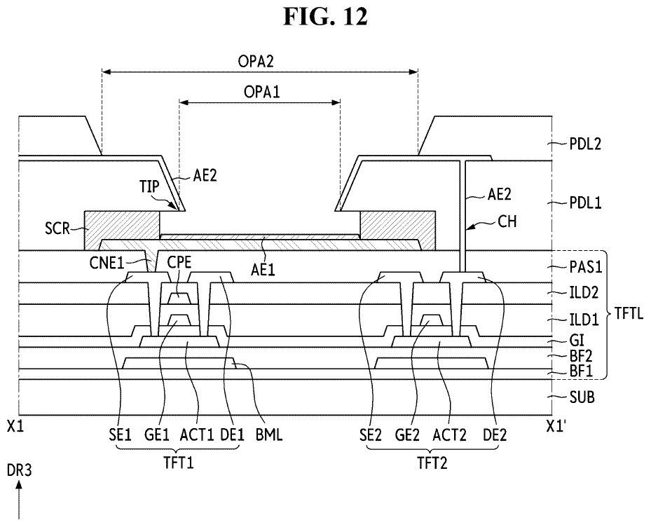

Subsequently, referring to FIG. 12, the first pixel electrode AE1 and the second pixel electrode AE2 are formed on the substrate SUB on which the contact hole CH is formed. The first pixel electrode AE1 and the second pixel electrode AE2 may be formed by stacking an electrode material layer on the substrate SUB and then patterning the electrode material layer by using a photo process. The electrode material layer is separated by the tip TIP of the first pixel defining layer PDL1, such that a portion of the electrode material layer stacked on the first connection electrode CNE1 may be formed as the first pixel electrode AE1 and a portion of the electrode material layer stacked on the first pixel defining layer PDL1 may be formed as the second pixel electrode AE2 through patterning. Accordingly, the first pixel electrode AE1 and the second pixel electrode AE2, which are separated from each other, are formed.

Subsequently, the second pixel defining layer PDL2 is formed on the first pixel defining layer PDL1 and the second pixel electrode AE2. The second pixel defining layer PDL2 may be formed using a solution process such as spin coating, inkjet printing, or slit coating. In addition, the second opening OPA2 exposing portions of upper surfaces of the second pixel electrode AE2 and the first pixel electrode AE1 is formed by using a photo process.

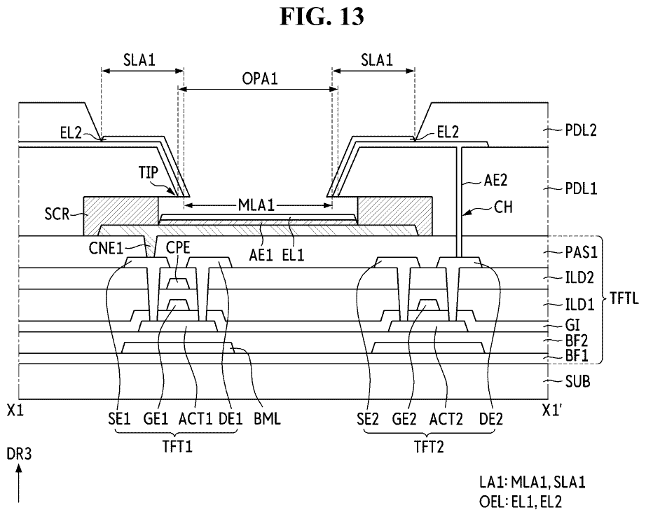

Next, referring to FIG. 13, the light emitting layer OEL is formed on the first opening OPA1 and the second opening OPA2. The light emitting layer OEL may be formed by depositing a light emitting material layer on the substrate SUB. The light emitting material layer is separated by the tip TIP of the first pixel defining layer PDL1, such that a portion of the light emitting material layer, which is deposited on the first pixel electrode AE1, may be formed as the first organic layer EL1 and a portion of the light emitting material layer, which is deposited on the second pixel electrode AE2, may be formed as the second organic layer EL2. Accordingly, the first organic layer EL1 and the second organic layer EL2, which are separated from each other, are formed.

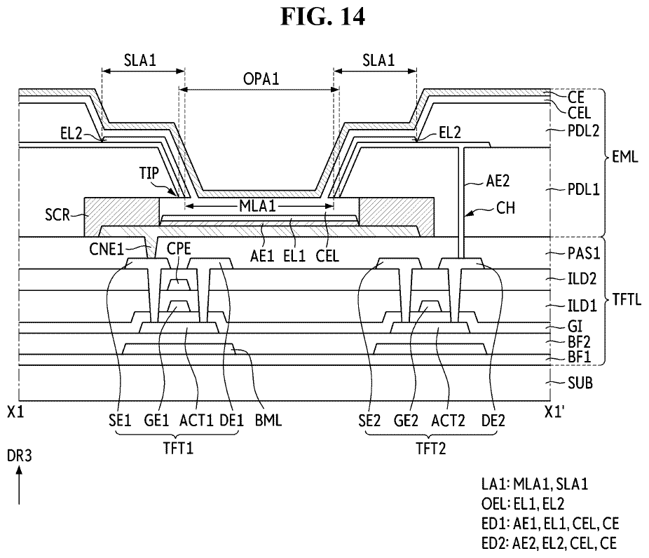

Subsequently, referring to FIG. 14, the common layer CEL and the common electrode CE are sequentially formed on the substrate SUB on which the light emitting layer OEL is formed. For example, the common layer CEL and the common electrode CE may be formed on the light emitting layer OEL. The common layer CEL may be formed by depositing a common material layer on the display area of the substrate SUB. The common layer CEL may be continuously deposited along the light emitting layer OEL while filling the first opening OPA1 of the first pixel defining layer PDL1. For example, the common layer CEL may fill an area partitioned by the first organic layer EL1, the sacrificial layer SCR, and the first pixel defining layer PDL1.

The common electrode CE may be formed by stacking a common electrode material layer on the display area of the substrate SUB. The common electrode CE may be continuously stacked and formed on the common layer CEL. Accordingly, the first light emitting element ED1, which includes the first pixel electrode AE1, the light emitting layer OEL, the common layer CEL, and the common electrode CE, and the second light emitting element ED2, which includes the second pixel electrode AE2, the light emitting layer OEL, the common layer CEL, and the common electrode CE are formed.

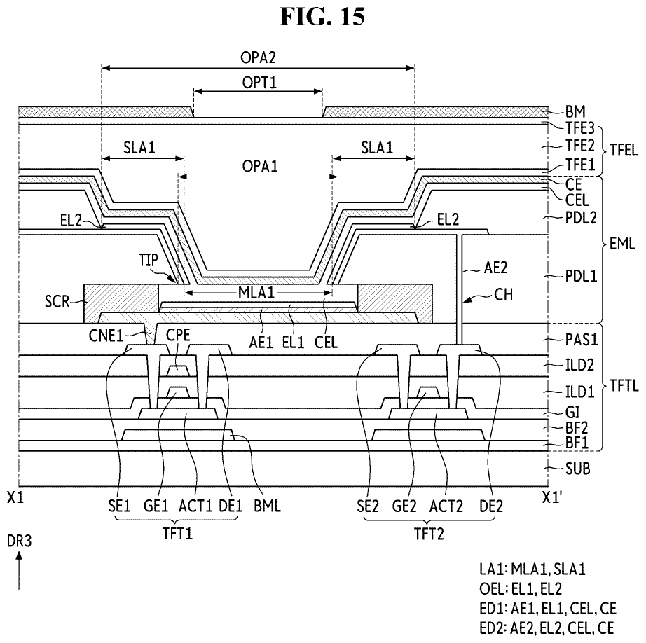

Next, referring to FIG. 15, the encapsulation layer TFEL is formed on the common electrode CE. The encapsulation layer TFEL may include the first encapsulation layer TFE1, the second encapsulation layer TFE2, and the third encapsulation layer TFE3 that are sequentially formed on the common electrode CE. The first encapsulation layer TFE1 and the third encapsulation layer TFE3 may be formed by using a chemical vapor deposition method or a physical vapor deposition method, and the second encapsulation layer TFE2 may be formed by using a solution process.

Subsequently, the light blocking layer BM is formed on the encapsulation layer TFEL. The light blocking layer BM may be formed to have the first hole OPT1 by forming a light shielding material layer on the third encapsulating layer TFE3 of the encapsulating layer TFEL and then using a photo process. Accordingly, the display device may be manufactured by the method of manufacturing the display device according to an embodiment of the present invention.

In the method for manufacturing the display device described above, the first pixel electrode AE1 and the second pixel electrode AE2 are separated from each other through a tip TIP structure of the first pixel defining layer PDL1. In addition, when forming the light emitting layer OEL, the tip TIP structure separates the light emitting layer OEL to form the first organic layer EL1 and the second organic layer EL2. Thus, a separate mask for forming the first pixel electrode AE1 and the second pixel electrode AE2, which are separated from each other, and the light emitting layer OEL including the first organic layer EL1 and the second organic layer EL2, which are separated from each other, may be omitted.

Hereinafter, display devices 10 according to embodiments of the present invention will be described with reference to other drawings.

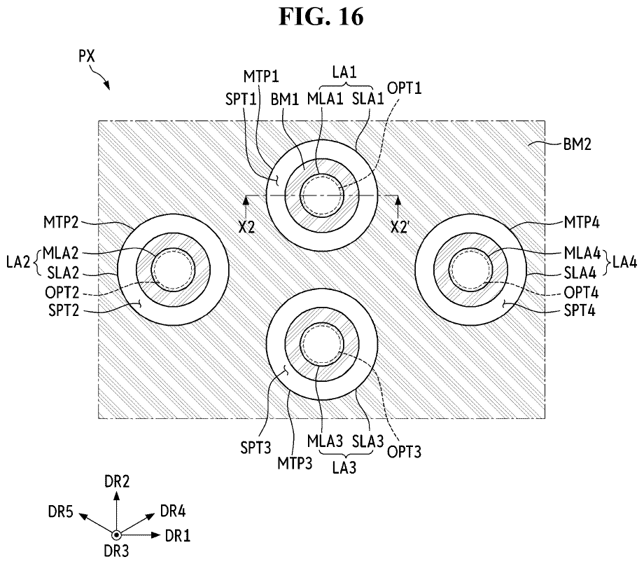

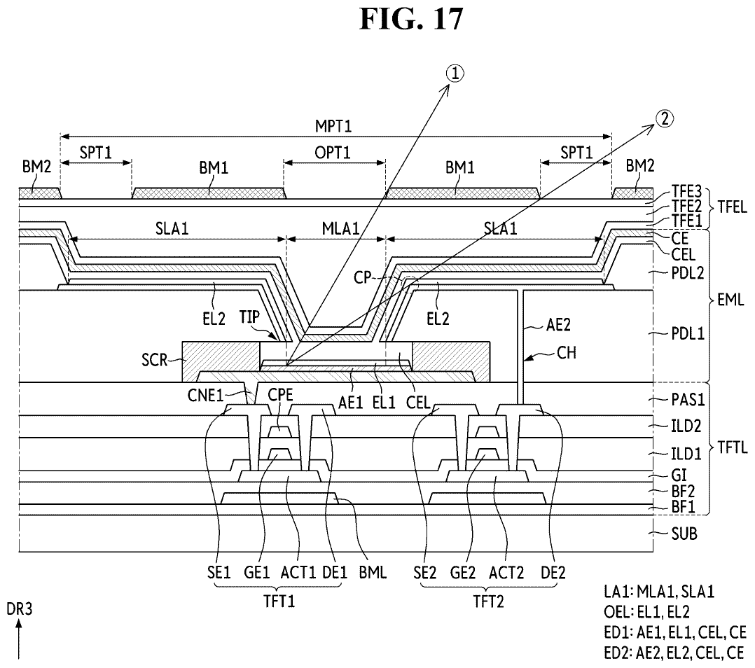

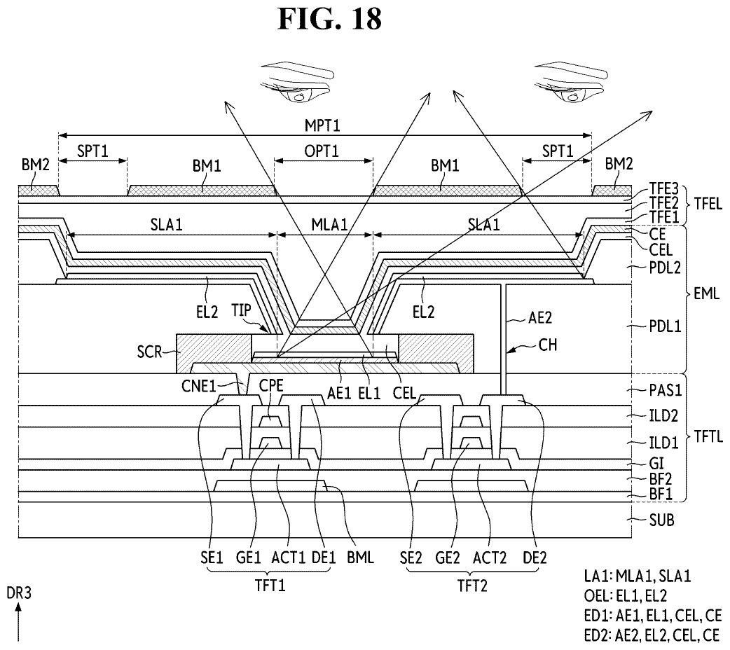

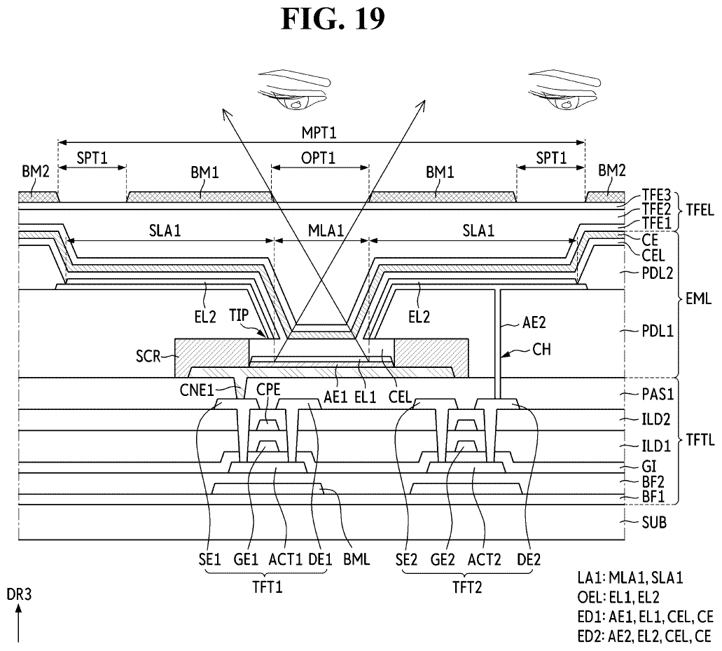

FIG. 16 is a plan view illustrating one pixel of a display device according to an embodiment of the present invention. FIG. 17 is a cross-sectional view taken along line X2-X2′ of FIG. 16. FIG. 18 is a schematic view illustrating light emission while the display device is operating in a first light emitting mode of the display device according to an embodiment of the present invention. FIG. 19 is a schematic view illustrating light emission while the display device is operating in a second light emitting mode according to an embodiment of the present invention.

Referring to FIGS. 16 and 17, the present embodiment is different from the embodiment described above with reference to FIGS. 5 to 8 in that each of emission areas LA1, LA2, LA3, and LA4 has a circular shape in plan view and a display device includes a first light blocking layer BM1 and a second light blocking layer BM2. Hereinafter, a description of contents overlapping those of the above-described embodiment will be omitted, and contents different from those of the above-described embodiment will be described.

As illustrated in FIG. 16, the display device 10 may include a pixel PX disposed in the display area DA. The pixel PX may include a plurality of emission areas LA1, LA2, LA3, and LA4. Each of the plurality of emission areas LA1, LA2, LA3, and LA4 may have a circular shape in plan view. It has been described by way of example in the present embodiment that each of the plurality of emission areas LA1, LA2, LA3, and LA4 has the circular shape, but the present invention is not limited thereto, and each of the plurality of emission areas LA1, LA2, LA3, and LA4 may also a polygonal shape other than a quadrangular shape.

The emission areas LA1, LA2, LA3, and LA4 may include main emission areas MLA1, MLA2, MLA3, and MLA4 and surrounding emission areas SLA1, SLA2, SLA3, and SLA4, respectively. For example, the first emission area LA1 may include a first main emission area MLA1 and a first surrounding emission area SLA1. The second emission area LA2 may include a second main emission area MLA2 and a second surrounding emission area SLA2, the third emission area LA3 may include a third main emission area MLA3 and a third surrounding emission area SLA3, and the fourth emission area LA4 may include a fourth main emission area MLA4 and a fourth surrounding emission area SLA4. Each of the main emission areas MLA1, MLA2, MLA3, and MLA4 of the emission areas LA1, LA2, LA3, and LA4 may correspond to a first opening OPA1 of a first pixel defining layer PDL1 (see FIG. 17), and each of the surrounding emission areas SLA1, SLA2, SLA3, and SLA4 of the emission areas LA1, LA2, LA3, and LA4 may correspond to a second opening OPA2 of a second pixel defining layer PDL2 (see FIG. 17).

Referring to FIGS. 16 and 17, the display device 10 may include the first light blocking layer BM1 and the second light blocking layer BM2 disposed on the respective emission areas LA1, LA2, LA3, and LA4.

A plurality of first light blocking layers BM1 may be provided and disposed to correspond to the plurality of emission areas LA1, LA2, LA3, and LA4, respectively. For example, the first light blocking layers BM1 may be disposed to surround portions of the respective emission areas LA1, LA2, LA3, and LA4 and overlap the respective emission areas LA1, LA2, LA3, and LA4 in plan view. For example, the first light blocking layers BM1 may each have a donut shape in which they partially cover the emission areas LA1, LA2, LA3, and LA4 and surround the emission areas LA1, LA2, LA3, and LA4 in plan view.

The first light blocking layers BM1 may include a plurality of holes OPT1, OPT2, OPT3, and OPT4 disposed to respectively correspond to the respective emission areas LA1, LA2, LA3, and LA4. In addition, the holes OPT1, OPT2, OPT3, and OPT4 of the first light blocking layers BM1 may be disposed to correspond to the openings OPA1 and OPA2 of the pixel defining layers PDL1 and PDL2 (see FIG. 17), respectively. The holes OPT1, OPT2, OPT3, and OPT4 of the first light blocking layers BM1 may be areas where light emitted from light emitting elements ED1 and ED2 corresponding to the respective emission areas LA1, LA2, LA3, and LA4 is emitted. The plurality of holes OPT1, OPT2, OPT3, and OPT4 may include a first hole OPT1, which overlaps the first emission area LA1, a second hole OPT2, which overlaps the second emission area LA2, a third hole OPT3, which overlaps the third emission area LA3, and a fourth hole OPT4, which overlaps the fourth emission area LA4.

As illustrated in FIG. 17, the first light blocking layer BM1 may be disposed on the encapsulation layer TFEL. The first light blocking layer BM1 may overlap the first pixel electrode AE1 and the second pixel electrode AE2, and may include the first hole OPT1 that overlaps the first main emission area MLA1. For example, the first hole OPT1 may be disposed to overlap the first pixel electrode AE1, the first organic layer EL1, the first main emission area MLA1, the first opening OPA1, and the second opening OPA2.

An area or a size of the first hole OPT1 may be smaller than an area or a size of the first pixel electrode AE1 and may be smaller than an area or a size of the first main emission area MLA1. In addition, the area or the size of the first hole OPT1 may be smaller than an area or a size of the first opening OPA1 of the first pixel defining layer PDL1. However, the present invention is not limited thereto, and the area or the size of the first hole OPT1 may also be the same as or greater than the area or the size of the first pixel electrode AE1 and be the same as or greater than the area or the size of the first main emission area MLA1 so that light emitted from the first main emission area MLA1 is not viewed by a user from a side surface of the display device 10. In addition, the area or the size of the first hole OPT1 may also be the same as or greater than the area or the size of the first opening OPA1 of the first pixel defining layer PDL1.

In an embodiment of the present invention, a width of the first light blocking layer BM1 may satisfy the following condition. A corner of the first light blocking layer BM1, where an upper surface and one side surface (e.g., an inner side surface) of the first light blocking layer BM1 meet, may meet an imaginary line \textcircled{1} that extends from an upper surface of the first pixel electrode AE1 and passes through a portion of the common electrode CE. For example, the portion of the common electrode CE may be a bent portion that overlaps the first pixel electrode AE1 and is adjacent to the tip TIP of the first pixel defining layer PDL1. In addition, a corner of the first light blocking layer BM1, where a lower surface and the other side surface (e.g., an outer side surface) of the first light blocking layer BM1 meet, may meet an imaginary line \textcircled{2} that extends from the upper surface of the first pixel electrode AE1, passes through a bent portion CP of the second organic layer EL2, and meets the end of the second pixel electrode AE2. Here, the bent portion CP of the second organic layer EL2 may be a portion of the second organic layer EL2 that corresponds to a portion of the first pixel defining layer PDL1 where an upper surface and a side surface of the first pixel defining layer PDL1 meet. For example, the end of the second pixel electrode AE2 may correspond to the portion of the first pixel defining layer PDL1 where the upper surface and the side surface of the first pixel defining layer PDL1 meet. Here, an angle at which the imaginary line \textcircled{1} extends may be about 60° or less based on the upper surface of the first pixel electrode AE1.

Referring to FIGS. 16 and 17, the second light blocking layer BM2 may be disposed on the encapsulation layer TFEL. The second light blocking layer BM2 may be disposed over the display area DA. For example, the second light blocking layer BM2 may be disposed over the entire display area DA. The second light blocking layer BM2 may include a plurality of main holes MPT1, MPT2, MPT3, and MPT4 disposed to respectively correspond to the plurality of emission areas LA1, LA2, LA3, and LA4. In addition, the main holes MPT1, MPT2, MPT3, and MPT4 of the second light blocking layer BM2 may be disposed to correspond to the openings OPA1 and OPA2 of the pixel defining layers PDL1 and PDL2 (see FIG. 17), respectively. The second light blocking layer BM2 may cover the display area DA except for an area of the display area DA where the main holes MPT1, MPT2, MPT3, and MPT4 are disposed. The main holes MPT1, MPT2, MPT3, and MPT4 of the second light blocking layer BM2 may be areas where light, which is emitted from the light emitting elements corresponding to the respective emission areas LA1, LA2, LA3, and LA4, is emitted from. The main holes MPT1, MPT2, MPT3, and MPT4 may include a first main hole MPT1, which overlaps the first emission area LA1, a second main hole MPT2, which overlaps the second emission area LA2, a third main hole MPT3, which overlaps the third emission area LA3, and a fourth main hole MPT4, which overlaps the fourth emission area LA4.

The first light blocking layers BM1 may be disposed in the main holes MPT1, MPT2, MPT3, and MPT4 of the second light blocking layer BM2. For example, the second light blocking layer BM2 may surround the first light blocking layers BM1. The second light blocking layer BM2 may be disposed to be spaced apart from the first light blocking layer BM1 and surround the first light blocking layers BM1 in plan view. An area of each of the main holes MPT1, MPT2, MPT3, and MPT4 of the second light blocking layer BM2 in plan view may be greater than an area of each of the emission areas LA1, LA2, LA3, and LA4 in plan view, and may be greater than an area of each of the first light blocking layers BM1.

Surrounding holes SPT1, SPT2, SPT3, and SPT4 may be disposed between the first light blocking layers BM1 and the second light blocking layer BM2. The surrounding holes SPT1, SPT2, SPT3, and SPT4 may be areas excluding the first light blocking layers BM1 and the holes OPT1, OPT2, OPT3, and OPT4 of each of the first light blocking layers BM1. For example, the surrounding holes SPT1, SPT2, SPT3, and SPT4 may be areas between inner side surfaces of the second light blocking layer BM2 and outer side surfaces of the first light blocking layer BM1. The surrounding holes SPT1, SPT2, SPT3, and SPT4 may be disposed to overlap the surrounding emission areas SLA1, SLA2, SLA3, and SLA4 and not overlap the main emission areas MLA1, MLA2, MLA3, and MLA4.

As illustrated in FIG. 17, the second light blocking layer BM2 may be disposed on the encapsulation layer TFEL, and may be disposed to be spaced apart from the first light blocking layer BM1. The second light blocking layer BM2 might not overlap the first pixel electrode AE1, and may at least partially overlap the second pixel electrode AE2. However, the present invention is not limited thereto, and the second light blocking layer BM2 might not overlap the second pixel electrode AE2. The first main hole MPT1 of the second light blocking layer BM2 may be disposed to overlap the first pixel electrode AE1, the first organic layer EL1, the first main emission area MLA1, the first opening OPA1 of the first pixel defining layer PDL1, and the second opening OPA2 of the second pixel defining layer PDL2.

In the display device 10 according to an embodiment of the present invention, side visibility may be adjusted according to light emitting modes of the first light emitting element ED1 and the second light emitting element ED2 in one emission area (e.g., the first emission area).

In the first light emitting mode, while the display device 10 is in a state in which the side visibility does not need to be limited, both the first light emitting element ED1 and the second light emitting element ED2 may emit light. As described above with reference to FIG. 4, in the first light emitting mode, a driving voltage is applied to the first pixel electrode AE1 through the first thin film transistor TFT1 (DTR in FIG. 4), such that the first light emitting element ED1 may emit light. In addition, the same driving voltage is applied to the second pixel electrode AE2 through the second thin film transistor TFT2 (STR7 in FIG. 4), such that the second light emitting element ED2 may emit light. As illustrated in FIG. 18, when both the first light emitting element ED1 and the second light emitting element ED2 emit the light in the first light emitting mode, the light emitted from the first emission area LA1 may be viewed by the user regardless of a direction from which the display device 10 is viewed.

In addition, in the second light emitting mode of the display device 10, while the display device 10 is in a state where the side visibility needs to be limited, only the first light emitting element ED1 may emit the light. In the second light emitting mode, the driving voltage is applied to the first pixel electrode AE1 through the first thin film transistor TFT1 (DTR in FIG. 4), such that the first light emitting element ED1 may emit the light. In addition, the driving voltage is not applied (e.g., is blocked) to the second pixel electrode AE2 by turning off the second thin film transistor TFT2 (STR7 in FIG. 4), such that the second light emitting element ED2 does not emit the light.

For example, as illustrated in FIG. 19, when only the first light emitting element ED1 emits the light in the second light emitting mode, the light may be emitted through the first hole OPT1 of the first light blocking layer BM1 and may be blocked by the first light blocking layer BM1 at specific viewing angles. In the second light emitting mode, since the second light emitting element ED2 does not emit the light, a screen of the display device 10 may be visible only to a user viewing it from the front of the display area DA of the display device 10 and might not be visible to someone viewing it at a specific viewing angle θ or from a side of the display area DA. Here, the specific viewing angle θ may be about 60° or less. Accordingly, the display device 10 may provide the privacy protection mode to the user.

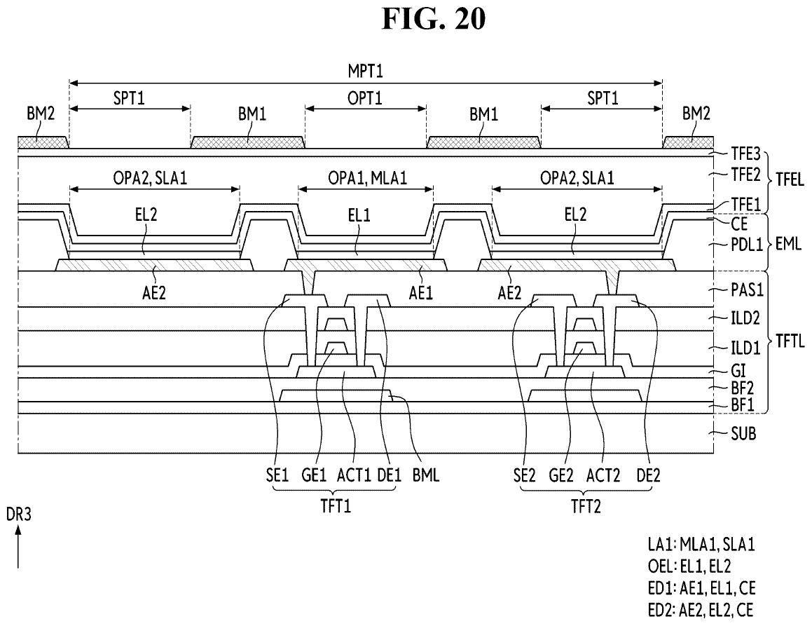

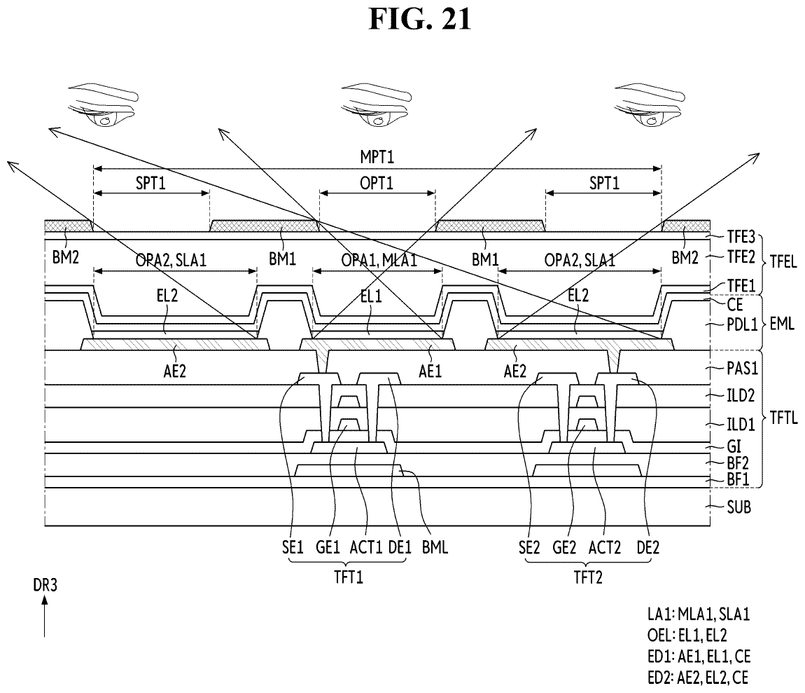

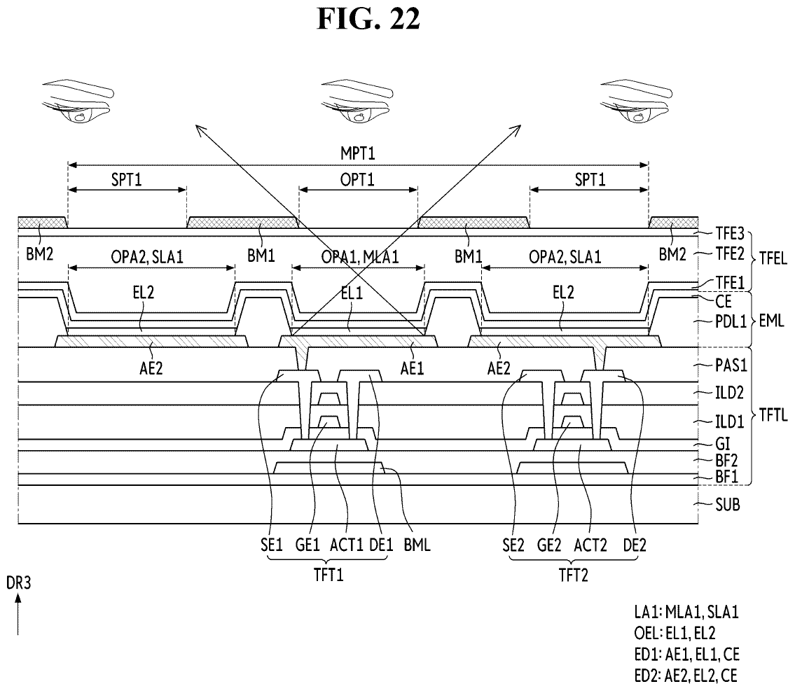

FIG. 20 is a cross-sectional view illustrating a display device according to an embodiment of the present invention. FIG. 21 is a schematic view illustrating light emission while the display device is operating in a first light emitting mode according to an embodiment of the present invention. FIG. 22 is a schematic view illustrating light emission while the display device is operating in a second light emitting mode according to an embodiment of the present invention.

Referring to FIG. 20, the present embodiment is different from another embodiment described above with reference to FIGS. 16 to 20 in that the first connection electrode CNE1, the second pixel defining layer PDL2, the common layer CEL, and the sacrificial layer SCR are omitted, and is the same as another embodiment described above with reference to FIG. 16 in an arrangement of respective emission areas LA1, LA2, LA3, and LA4.

In a display device 10 according to an embodiment of the present invention, a first pixel electrode AE1 and a second pixel electrode AE2 may be disposed on the first passivation layer PAS1. The second pixel electrode AE2 may be disposed to be spaced apart from the first pixel electrode AE1 and at least partially surround the first pixel electrode AE1 in plan view. The first pixel defining layer PDL1 may include a first opening OPA1 and a second opening OPA2 respectively exposing the first pixel electrode AE1 and the second pixel electrode AE2. For example, the first opening OPA1 may overlap the first pixel electrode AE1 to expose the first pixel electrode AE1, and the second opening OPA2 may overlap the second pixel electrode AE2 to expose the second pixel electrode AE2.

The light emitting layer OEL may include a first organic layer EL1 and a second organic layer EL2. The first organic layer EL1 and the second organic layer EL2 may emit light of the same color, and may be formed by the same process. The first organic layer EL1 may overlap the first opening OPA1 and be disposed on the first pixel electrode AE1, and the second organic layer EL2 may overlap the second opening OPA2 and be disposed on the second pixel electrode AE2.

The common electrode CE may be continuously disposed on the light emitting layer OEL and the first pixel defining layer PDL1. Accordingly, the display device 10 may include a first light emitting element ED1, which includes the first pixel electrode AE1, the first organic layer EL1, and the common electrode CE, and a second light emitting element ED2, which includes the second pixel electrode AE2, the second organic layer EL2, and the common electrode CE, within the first emission area LA1. The first light emitting element ED1 may include a first main emission area MLA1, and the second light emitting element ED2 may include a first surrounding emission area SLA1. The first main emission area MLA1 and the first surrounding emission area SLA1 do not overlap each other.

The encapsulation layer TFEL may be disposed on the common electrode CE, and the first light blocking layer BM1 and the second light blocking layer BM2 may be disposed on the encapsulation layer TFEL.

The first blocking layer BM1 and the second blocking layer BM2 may be disposed on the encapsulation layer TFEL so as to be spaced apart from each other. The first light blocking layer BM1 may overlap the first pixel electrode AE1 and the second pixel electrode AE2, and may include the first hole OPT1 that overlaps the first main emission area MLA1. For example, the first hole OPT1 may be disposed to overlap the first pixel electrode AE1, the first organic layer EL1, the first main emission area MLA1, and the first opening OPA1. The second light blocking layer BM2 might not overlap the first pixel electrode AE1, and may at least partially overlap the second pixel electrode AE2. The second blocking layer BM2 may include a first main hole MPT1 overlapping the first main emission area MLA1 and the first surrounding emission area SLA1. The first main hole MPT1 of the second light blocking layer BM2 may be disposed to overlap the first pixel electrode AE1, the second pixel electrode AE2, the first organic layer EL1, the second organic layer EL2, the first main emission area MLA1, the first surrounding emission area SLA1, the first opening OPA1, and the second opening OPA2.

The first light blocking layer BM1 may be disposed in the first main hole MPT1 of the second light blocking layer BM2. For example, the first main hole MPT1 of the second light blocking layer BM2 may overlap the first light blocking layer BM1. An area of the first main hole MPT1 of the second light blocking layer BM2 in plan view may be greater than an area of the first emission area LA1 in plan view, and may be greater than an area of the first light blocking layer BM1.

A first surrounding hole SPT1 may be disposed between the first light blocking layer BM1 and the second light blocking layer BM2. The first surrounding hole SPT1 may be an area excluding the first light blocking layer BM1 and the first hole OPT1 within the first main hole MPT1. For example, the first surrounding hole SPT1 may be an area between an inner side surface of the second light blocking layer BM2 and an outer side surface of the first light blocking layer BM1. The first surrounding hole SPT1 may be disposed to overlap the first surrounding emission area SLA1 and not overlap the first main emission area MLA1.

In the display device 10 according to an embodiment of the present invention, side visibility may be adjusted according to light emitting modes of the first light emitting element ED1 and the second light emitting element ED2 in one emission area (e.g., the first emission area).

In the first light emitting mode, while the display device 10 is in a state in which the side visibility does not need to be limited, both the first light emitting element ED1 and the second light emitting element ED2 may emit light. As described above with reference to FIG. 4, in the first light emitting mode, a driving voltage is applied to the first pixel electrode AE1 through the first thin film transistor TFT1 (DTR in FIG. 4), such that the first light emitting element ED1 may emit light. In addition, the same driving voltage is applied to the second pixel electrode AE2 through the second thin film transistor TFT2 (STR7 in FIG. 4), such that the second light emitting element ED2 may emit light. As illustrated in FIG. 21, when both the first light emitting element ED1 and the second light emitting element ED2 emit the light in the first light emitting mode, the light is emitted through the first main hole MPT1 of the second light blocking layer BM2 (e.g., the first hole OPT1 of the first light blocking layer BM1 and the first surrounding hole SPT1), such that the light emitted from the first emission area LA1 may be viewed by the user regardless of a direction from which the display device 10 is viewed.

In addition, in the second light emitting mode of the display device 10, while the display device 10 in a state where the side visibility needs to be limited, only the first light emitting element ED1 may emit the light. In the second light emitting mode, the driving voltage is applied to the first pixel electrode AE1 through the first thin film transistor TFT1 (DTR in FIG. 4), such that the first light emitting element ED1 may emit the light. In addition, the driving voltage is not applied (e.g., is blocked) to the second pixel electrode AE2 by turning off the second thin film transistor TFT2 (STR7 in FIG. 4), such that the second light emitting element ED2 does not emit the light.

For example, as illustrated in FIG. 22, when only the first light emitting element ED1 emits the light in the second light emitting mode, the light may be emitted through the first hole OPT1 of the first light blocking layer BM1 and may be blocked by the first light blocking layer BM1 at specific viewing angles. In the second light emitting mode, since the second light emitting element ED2 does not emit the light, in the second light emitting mode, a screen of the display device 10 may be visible only to a user viewing it from the front of the display area DA of the display device 10 and might not be visible to someone viewing it at a specific viewing angle θ or from a side of the display area DA. Here, the specific viewing angle θ may be about 60° or less. Accordingly, the display device 10 may provide the privacy protection mode to the user.

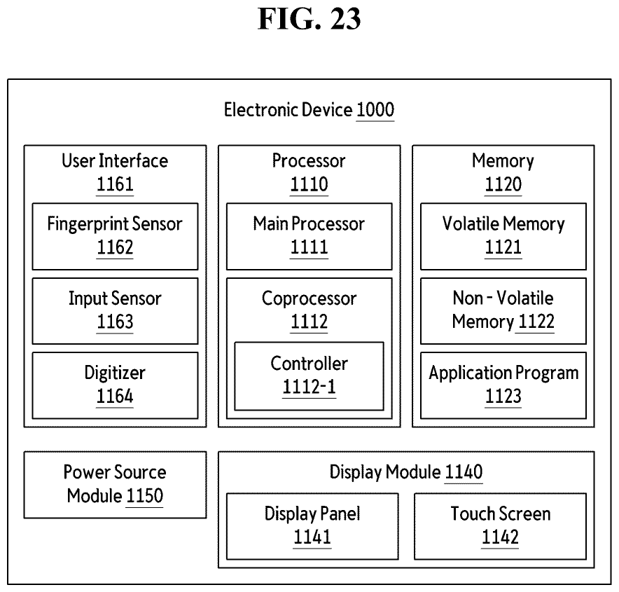

FIG. 23 is a diagram illustrating an electronic device according to an embodiment of the present invention. Referring to FIG. 23, the electronic device 1000 according to an embodiment of the present invention may output various information (e.g., images, text, music, etc.) through a display module 1140, which, for example, may correspond to the display device 10 shown in FIG. 2. When a processor 1110 executes an application stored in a memory 1120, the display module 1140 may provide application information to a user through a display panel 1141.

In some embodiments of the present invention, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including the display area DA optimized for compact and high-clarity visuals and the non-display area NDA integrating biometric sensors for health monitoring. In some cases, the electronic device 1000 may be an AR/VR headset.

In some embodiments of the present invention, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

For example, the disclosure about the electronic device 1000 of FIG. 23 may be combinable with the disclosure about the electronic device 1 of FIG. 1.

While the present invention has been particularly shown and described with reference to embodiments thereof, it will be apparent to those of ordinary skill in the art that various changes in form and detail may be made thereto without departing from spirit and scope of the present invention.

What is claimed is:

1. A display device comprising:
a substrate;
a first thin film transistor and a second thin film transistor disposed on the substrate;
a passivation layer disposed on the first thin film transistor and the second thin film transistor;
a connection electrode disposed on the passivation layer and connected to the first thin film transistor;
a sacrificial layer covering an edge of the connection electrode;
a first pixel defining layer disposed on the passivation layer and the sacrificial layer and including a first opening;
a first pixel electrode disposed on the connection electrode;
a second pixel electrode disposed on the first pixel defining layer and connected to the second thin film transistor;
a second pixel defining layer disposed on the first pixel defining layer and the second pixel electrode and including a second opening that overlaps the first opening;
a light emitting layer including a first organic layer and a second organic layer, wherein the first organic layer is disposed on the first pixel electrode, and the second organic layer is disposed on the second pixel electrode;
a common layer disposed on the light emitting layer and the second pixel defining layer;
a common electrode disposed on the common layer;
an encapsulation layer disposed on the common electrode; and
a light blocking layer disposed on the encapsulation layer and including a hole that overlaps the first opening and the second opening.

2. The display device of claim 1, wherein a side surface and lower surface of the first pixel defining layer form a tip that protrudes beyond a side surface of the sacrificial layer.

3. The display device of claim 2, wherein the first pixel electrode and the second pixel electrode are separated from each other by the tip of the first pixel defining layer.

4. The display device of claim 2, wherein the first organic layer and the second organic layer are separated from each other by the tip of the first pixel defining layer.

5. The display device of claim 1, further comprising:
a first light emitting element including the first pixel electrode, the first organic layer, the common layer, and the common electrode; and
a second light emitting element including the second pixel electrode, the second organic layer, the common layer, and the common electrode.

6. The display device of claim 5, wherein the first light emitting element overlaps the first opening, and includes a main emission area that extends to an inner peripheral surface of the second pixel electrode, and
the second light emitting element includes a surrounding emission area where the second pixel electrode, the second organic layer, the common layer, and the common electrode overlap each other in a thickness direction.

7. The display device of claim 6, wherein the main emission area overlaps the first opening, the second opening, and the hole, and the surrounding emission area does not overlap the first opening and the hole and overlaps the second opening.

8. The display device of claim 1, wherein in a first light emitting mode, a same driving voltage is applied to the first pixel electrode and the second pixel electrode through the first thin film transistor and the second thin film transistor, such that light is emitted from the light emitting layer.

9. The display device of claim 1, wherein in a second light emitting mode, a driving voltage is applied to the first pixel electrode through the first thin film transistor, such that light is emitted from the first organic layer of the light emitting layer, and the second thin film transistor is in an off state and the driving voltage is not applied to the second pixel electrode, such that light is not emitted from the second organic layer of the light emitting layer.

10. The display device of claim 1, wherein the light blocking layer overlaps the first pixel electrode and the second pixel electrode.

11. The display device of claim 1, wherein the light blocking layer includes a first light blocking layer and a second light blocking layer, wherein the first light blocking layer includes the hole, and the second light blocking layer is spaced apart from the first light blocking layer and surrounds the first light blocking layer.

12. The display device of claim 11, further comprising a surrounding hole disposed between the first light blocking layer and the second light blocking layer,
wherein the surrounding hole does not overlap the first opening and overlaps the second opening.

13. The display device of claim 11, wherein a corner of the first light blocking layer, where a lower surface and a side surface of the first light blocking layer meet, meets a line that extends from an upper surface of the first pixel electrode, passes through a bent portion of the second organic layer, and meets an end of the second pixel electrode, wherein the bent portion of the second organic layer corresponds to a portion of the first pixel defining layer where an upper surface and a side surface of the first pixel defining layer meet.

14. A display device comprising a plurality of pixels each including a plurality of sub-pixels,
wherein each of the plurality of sub-pixels includes:
a substrate;
a first thin film transistor and a second thin film transistor disposed on the substrate;
a passivation layer disposed on the first thin film transistor and the second thin film transistor;
a first pixel electrode disposed on the passivation layer and connected to the first thin film transistor;
a second pixel electrode disposed on the passivation layer and connected to the second thin film transistor;
a pixel defining layer covering an edge of each of the first pixel electrode and the second pixel electrode and including a first opening and a second opening, wherein the first opening overlaps the first pixel electrode, and the second opening overlaps the second pixel electrode;
a light emitting layer including a first organic layer and a second organic layer, wherein the first organic layer is disposed on the first pixel electrode, and the second organic layer is disposed on the second pixel electrode;
a common electrode disposed on the light emitting layer and the pixel defining layer;
an encapsulation layer disposed on the common electrode;
a first light blocking layer disposed on the encapsulation layer and including a hole overlapping the first opening; and
a second light blocking layer disposed on the encapsulation layer, and surrounding the first light blocking layer, wherein the second light blocking layer includes a main hole overlapping the first light blocking layer.

15. The display device of claim 14, further comprising:
a first light emitting element including the first pixel electrode, the first organic layer, and the common electrode; and
a second light emitting element including the second pixel electrode, the second organic layer, and the common electrode.

16. The display device of claim 15, wherein the first light emitting element includes a main emission area overlapping the first opening and the hole, and the second light emitting element includes a surrounding emission area that overlaps the main hole but does not overlap the main emission area.

17. The display device of claim 16, wherein in a first light emitting mode, a same driving voltage is applied to the first pixel electrode and the second pixel electrode through the first thin film transistor and the second thin film transistor, such that the first light emitting element and the second light emitting element emit light, and
the light is emitted through the hole of the first light blocking layer and the main hole of the second light blocking layer while in the first light emitting mode.

18. The display device of claim 16, wherein in a second light emitting mode, a driving voltage is applied to the first pixel electrode through the first thin film transistor, such that the first light emitting element emits light, and the second thin film transistor is in an off state and the driving voltage is not applied to the second pixel electrode, such that the second light emitting element does not emit light, and
the light emitted from the first light emitting element is emitted through the hole of the first light blocking layer while in the second light emitting mode.

19. The display device of claim 16, further comprising a surrounding hole disposed between the first light blocking layer and the second light blocking layer,
wherein the surrounding hole does not overlap the main emission area and overlaps the surrounding emission area.

20. An electronic device comprising:
a processor;
a memory having stored application programs for execution by the processor;
a display device, comprising:
a substrate;
a first thin film transistor and a second thin film transistor disposed on the substrate;
a passivation layer disposed on the first thin film transistor and the second thin film transistor;
a connection electrode disposed on the passivation layer and connected to the first thin film transistor;
a sacrificial layer covering an edge of the connection electrode;
a first pixel defining layer disposed on the passivation layer and the sacrificial layer and including a first opening;
a first pixel electrode disposed on the connection electrode;
a second pixel electrode disposed on the first pixel defining layer and connected to the second thin film transistor;
a second pixel defining layer disposed on the first pixel defining layer and the second pixel electrode and including a second opening that overlaps the first opening;
a light emitting layer including a first organic layer and a second organic layer, wherein the first organic layer is disposed on the first pixel electrode, and the second organic layer is disposed on the second pixel electrode;
a common layer disposed on the light emitting layer and the second pixel defining layer;
a common electrode disposed on the common layer;
an encapsulation layer disposed on the common electrode; and
a light blocking layer disposed on the encapsulation layer and including a hole that overlaps the first opening and the second opening; and
a user interface configured to sense user input via touch or cursor select of an icon presented on the display device, wherein the processor is caused to execute one or more of the stored application programs upon receipt of the user input.
